(19) United States
(12) Patent Application Publication
(10) Pub. No.: US 2025/0393240 A1
(43) Pub. Date: Dec. 25, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Kuei-Yu Kao, Hsinchu (TW); Tse-Yi Chi, Hsinchu (TW); Shih-Yao Lin, Taipei (TW); Chen-Chin Liao, Yilan (TW); Chun-Yu Lin, Yilan (TW); Yung-Chi Chang, Hsinchu (CN)

(73) Assignee: Taiwan Semiconductor Manufacturing Company, Ltd., Hsinchu (TW)

(21) Appl. No.: 18/753,293

(22) Filed: Jun. 25, 2024

(51) Int. Cl. H01L 29/78; H01L 29/06; H01L 29/423; H01L 29/66; H01L 29/775; H01L 29/786

(52) U.S. Cl. CPC H10D 30/62; H10D 30/014; H10D 30/024; H10D 30/43; H10D 30/6735; H10D 30/6757; H10D 62/121; H10D 64/017; H10D 64/018

(57) ABSTRACT

A semiconductor fabrication method includes: forming, on a substrate, an epitaxial stack including at least one sacrificial epitaxial layer and at least one channel epitaxial layer; forming a plurality of fins in the epitaxial stack; forming a stop cap layer over the plurality of fins and substrate, the stop cap layer formed with a substantial concentration of nitrogen (N); forming a sacrificial gate stack on channel regions of the plurality of fins; removing the sacrificial gate stack and sacrificial epitaxial layer; and forming a metal gate, wherein the metal gate is shielded from source/drain features by a gate sidewall spacer, an inner spacer, and a first liner formed from the stop cap layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method of semiconductor fabrication including fabrication of multi-gate devices, in accordance with some embodiments.

FIGS. 2-4, 5B-5C, 6A, 7A, and 8-15 are cross-sectional side views of an embodiment of an example semiconductor device at various stages of fabrication in an example fabrication process in accordance with some embodiments.

FIGS. 5A, 6B, and 7B are three-dimensional schematic views of a portion of the example semiconductor device at various stages of fabrication in an example fabrication process, in accordance with some embodiments.

FIG. 16A is a schematic diagram depicting a plane view of the gate structure of FIG. 15, and FIG. 16B is a schematic diagram providing an alternative plane view of the gate structure of FIG. 15, in accordance with some embodiments.

FIGS. 17A and 18A-18D depict schematic diagrams of a semiconductor structure at a phase of fabrication after dummy gate patterning, in accordance with some embodiments.

FIGS. 17B and 19A-19D depict schematic diagrams of another semiconductor structure at a phase of fabrication after dummy gate patterning, in accordance with some embodiments.

FIGS. 20A-20C are schematic diagrams illustrating example effects of including Nitrogen in a stop layer formed from SiO.

FIG. 21A provides schematic diagrams illustrating example effects of a stop layer in semiconductor structures at a phase of fabrication after dummy gate patterning, in accordance with some embodiments.

FIG. 21B is a schematic diagram illustrating example effects of a stop layer in semiconductor structures at a phase of fabrication after S/D formation, in accordance with some embodiments.

FIG. 21C is a schematic diagram illustrating example effects of a stop layer in semiconductor structures at a phase of fabrication after metal gate replacement, in accordance with some embodiments.

FIGS. 22A-22C provide schematic diagrams illustrating example dimensions of potential defects formed in semiconductor structures at a phase of fabrication after dummy gate patterning, in accordance with some embodiments.

FIGS. 23A-23B provide schematic diagrams illustrating example dimensions of semiconductor structures at a phase of fabrication after metal gate replacement, in accordance with some embodiments.

FIGS. 24A-24C provide schematic diagrams illustrating example features of a semiconductor structure at a phase of fabrication after metal gate replacement, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Various embodiments are discussed herein in a particular context, namely, for forming a semiconductor structure that includes a fin-like field-effect transistor (FinFET) device. The semiconductor structure, for example, may be a complementary metal-oxide-semiconductor (CMOS) device including a P-type metal oxide-semiconductor (PMOS) FinFET device and an N-type metal-oxide semiconductor (NMOS) FinFET device. Embodiments will now be described with respect to particular examples including FinFET manufacturing processes. Embodiments, however, are not limited to the examples provided herein, and the ideas may be implemented in a wide array of embodiments. Thus, various embodiments may be applied to other semiconductor devices/processes, such as planar transistors, and the like. Further, some embodiments discussed herein are discussed in the context of devices formed using a gate-last process. In other embodiments, a gate-first process may be used.

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and more particularly to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. However, one of ordinary skill would recognize that the teaching can apply to a single channel or any number of channels, such as a FinFET device, on account of its fin-like structure. One of ordinary skill may recognize other examples of semiconductor devices that may benefit from aspects of the present disclosure.

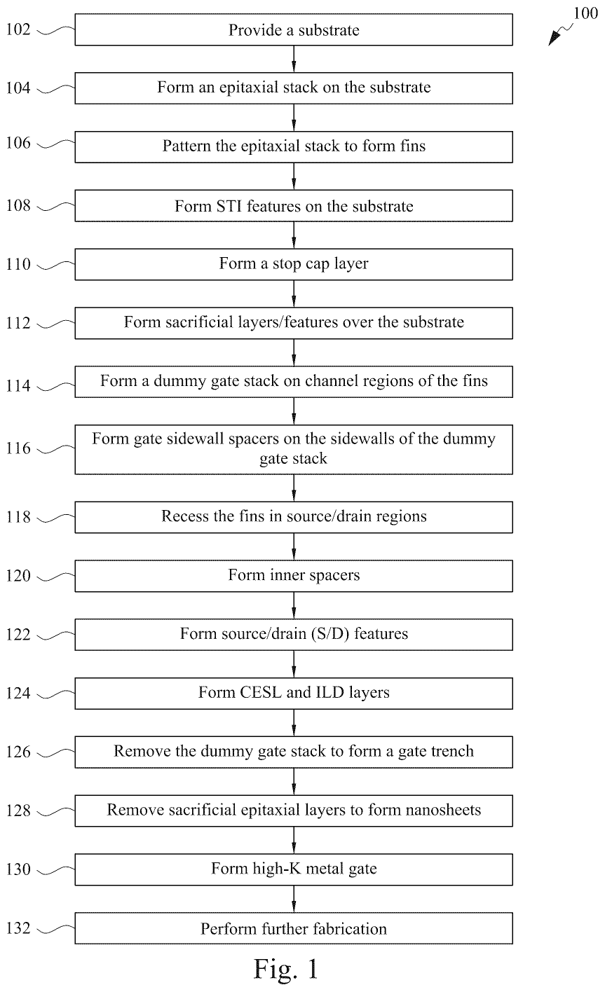

FIG. 1 is a flow chart depicting an example method 100 of semiconductor fabrication including fabrication of multi-gate devices. according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

FIG. 1 is described in conjunction with FIGS. 2-4, 5A-5C, 6A-6B, 7A-7B, and 8-15, which illustrate a semiconductor device 200 or structure at various stages of fabrication in accordance with some embodiments. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor device 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

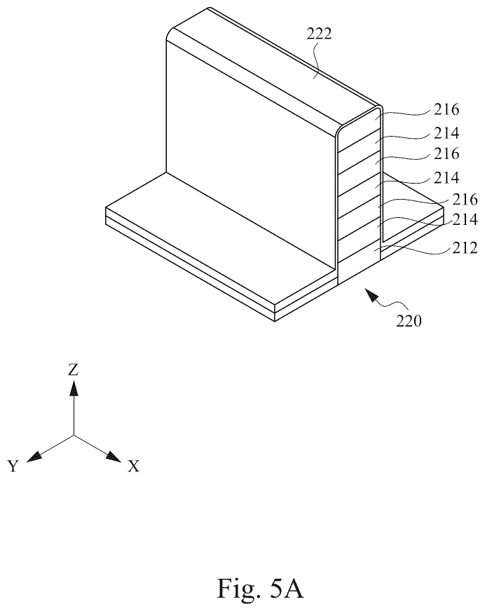

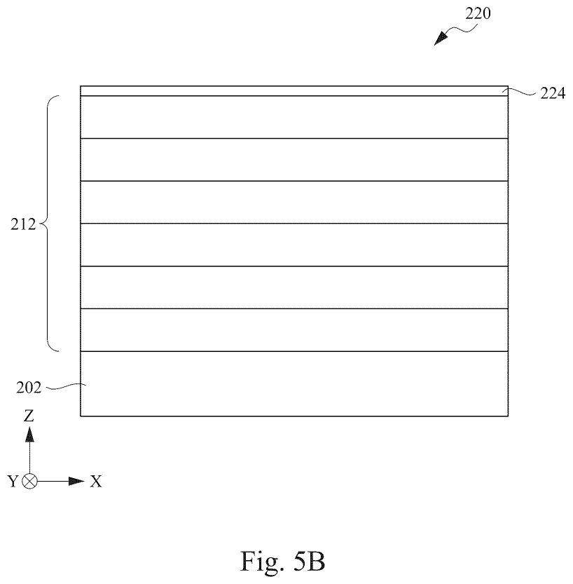

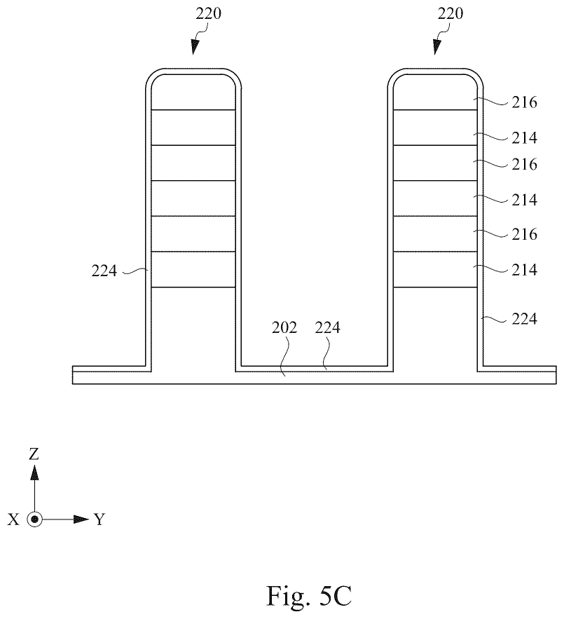

FIGS. 2-4, 5B-5B, 6A, 7A, and 8-15 are cross-sectional side views of an embodiment of the example semiconductor device 200 at various stages of fabrication in an example fabrication process in accordance with some embodiments. FIGS. 5A, 6B, and 7B are three-dimensional schematic views of a portion of the example semiconductor device 200 at various stages of fabrication in an example fabrication process in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIG. 2, in an embodiment of block 102, a substrate 202 is provided for forming a multi-gate device 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

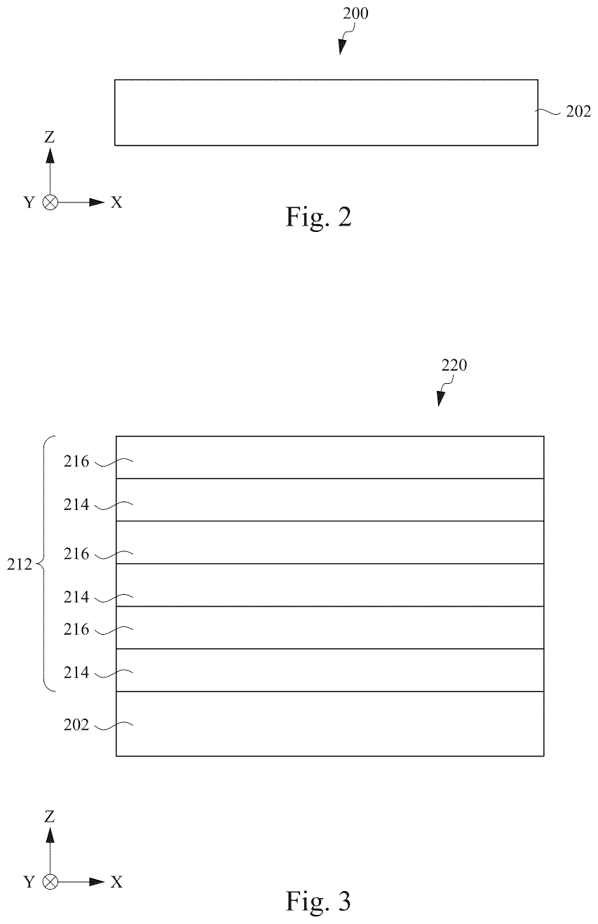

At block 104, the example method 100 then includes forming an epitaxial stack comprising one or more epitaxial layers over the substrate. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the device 200. In some embodiments, the number of channel epitaxial layers 216 is between 2 and 10, such as 3, 4 or 5.

In some embodiments, the sacrificial epitaxial layer 214 has a thickness ranging from about 4 nm to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25^{˜}55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AllnAs, AlGaAs, InGaAs, GalnP, and/or GalnAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

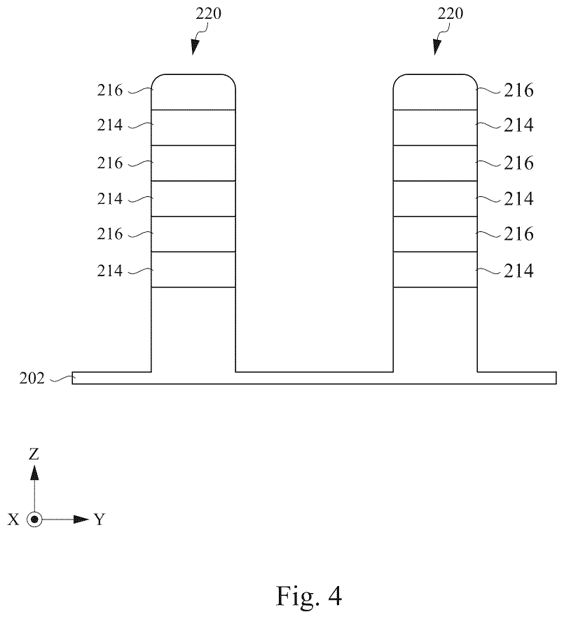

At block 106, the example method 100 includes patterning the epitaxial stack to form semiconductor fins (also referred to as fins). Referring to the example of FIG. 4, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 108, the example method 100 includes forming STI features on the substrate. In various embodiments, the STI features are formed by filling trenches between adjacent fins with a dielectric material to form an isolation feature. The STI features may include one or more dielectric layers. Suitable dielectric materials for the STI features may include silicon oxides, silicon nitrides, silicon carbides, fluorosilicate glass (FSG), low-K dielectric materials, and/or other suitable dielectric materials. The dielectric material may be deposited by any suitable technique including thermal growth, CVD, HDP-CVD, PVD, ALD, and/or spin-on techniques. The deposited STI features are subsequently recessed to form shallow trench isolation (STI) features. Any suitable etching technique may be used to recess the isolation features including dry etching, wet etching, RIE, and/or other etching methods, and in an exemplary embodiment, an anisotropic dry etching is used to selectively remove the dielectric material of the isolation features without etching the fins.

At block 110, the example method 100 includes forming a stop cap layer over the fins and substrate. Referring to the example of FIGS. 5A, 5B, and 5C, in an embodiment of forming a stop cap layer over the fins and substrate, a stop cap layer 222 is blanket deposited the over the fins 220 and the substrate 202. In various embodiments, the stop cap layer 222 is formed from a Nitride, such as SiON, wherein the concentration of nitrogen (N) in the Nitride (e.g., SiON) is approximately 2 to 10%. In various embodiments, the concentration of nitrogen (N) in the SiON is approximately 7-8%. Adding N can improve the etching rate. However, If the concentration is too high, it can cause pitting. In various embodiments, the stop cap layer 222 may be deposited using CVD, including LPCVD and PECVD, PVD, ALD, or other suitable processes.

In various embodiments the stop cap layer 222 may be deposited via a plasma treatment in a plasma chamber. Example parameters for the plasma treat may include the following. The passivation gas for selectivity may comprise N₂, O₂, NHₓ, CHₓ, or others. The Dilute gas may comprise He, Ar, or others. The Power may be in the range of 10 W to approximately 4000 W. The Pressure may be in the range of 1 mTorr to approximately 800 mTorr. The gas flow may be in the range of 20 sccm to approximately 3000 sccm.

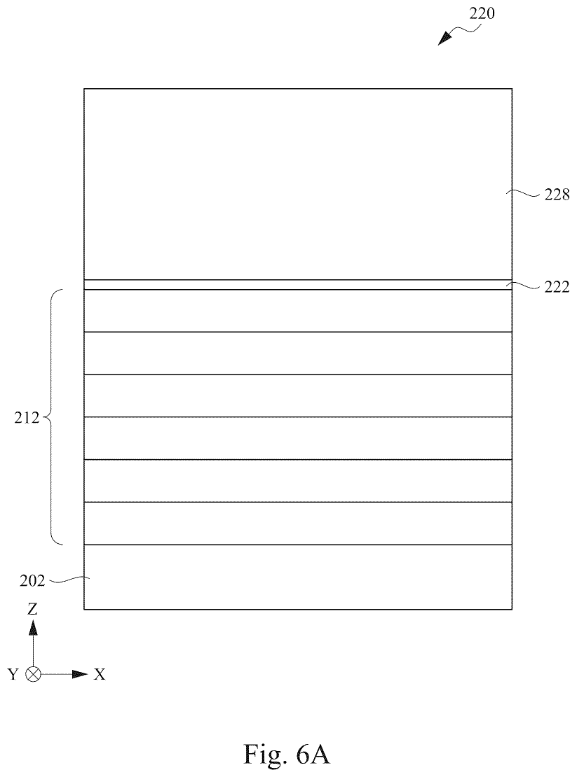

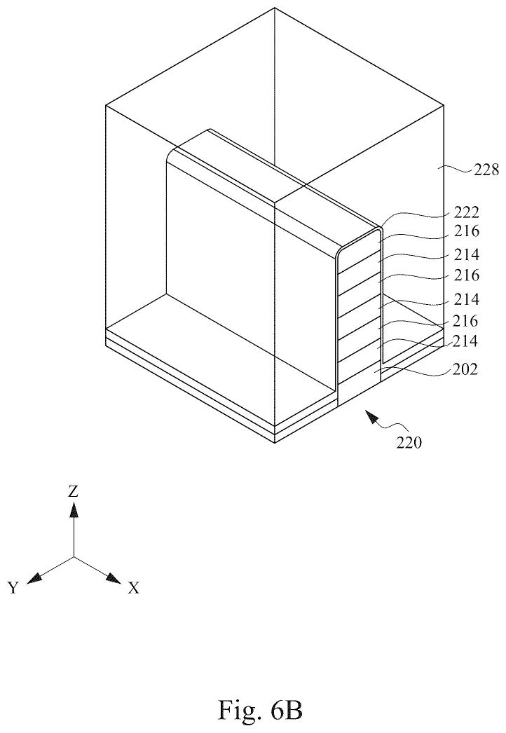

At block 112, the example method 100 includes forming one or more sacrificial layers/features over the substrate. Referring to the example of FIGS. 6A and 6B, in an embodiment of forming one or more sacrificial layers/features over the substrate, a sacrificial gate dielectric layer (not shown) is blanket deposited the over the fins 220. A sacrificial gate electrode layer 228 is then blanket deposited on the sacrificial gate dielectric layer and over the fins 220. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

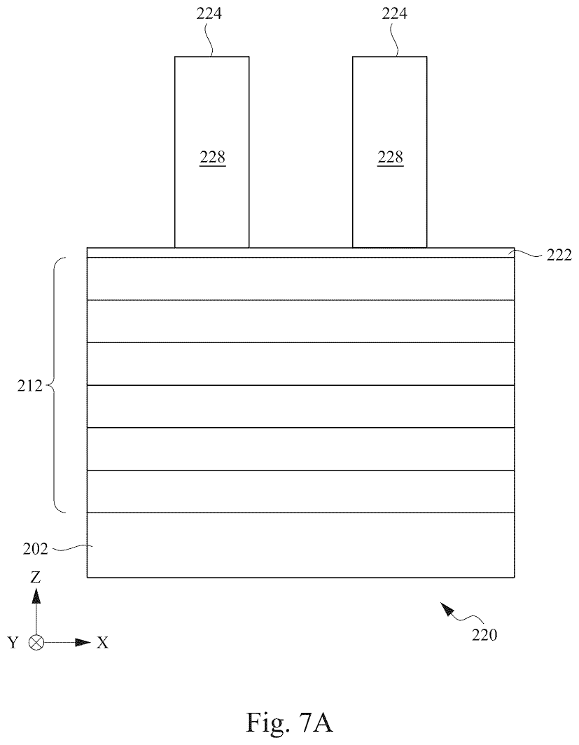

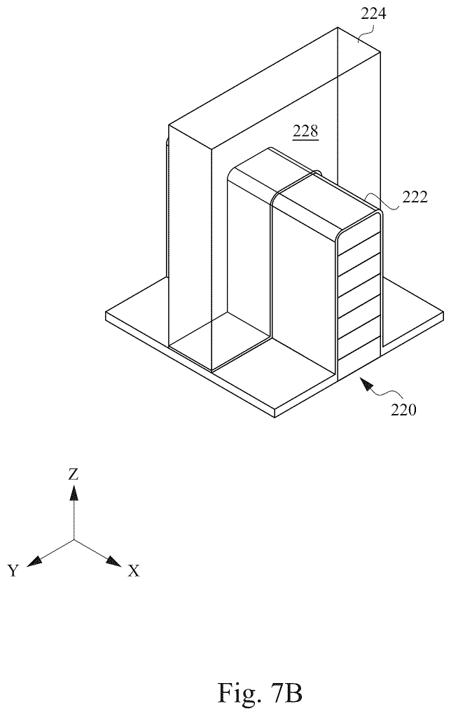

At block 114, the example method 100 includes patterning the one or more sacrificial layers/features to form a dummy gate structure on channel regions of the fins. Referring to the example of FIGS. 7A and 7B, in an embodiment of block 114, a sacrificial gate structure 224 is formed over portions of the fins 220 which is to be channel regions. The sacrificial gate structure 224 defines the channel regions of the GAA devices. The sacrificial gate structure 224 includes a sacrificial gate dielectric layer (not shown) and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The stop cap layer 222 prevents or substantially eliminates the formation of dummy gate related defects during dummy gate patterning operations. The prevention or substantial elimination of the dummy gate related defects allows for subsequently formed gate spacers and inner gate spacers to isolate the subsequently formed metal gate from the subsequently formed source/drain regions. Also, portions of the stop cap layer 222 cooperate with the subsequently formed gate spacers and inner gate spacers to isolate the subsequently formed metal gate from the subsequently formed source/drain regions.

The sacrificial gate structure 224 is subsequently removed as discussed with reference to block 126 of the method 100 and will be replaced by a final gate stack at a subsequent processing stage of the device 200. In particular, the sacrificial gate structure 224 is replaced at a later processing stage by a high-K dielectric layer (HK) and metal gate electrode (MG) as discussed below.

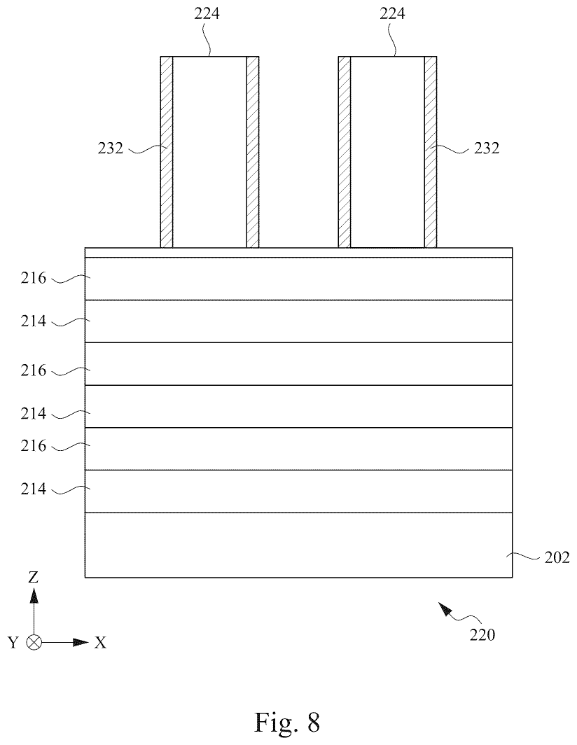

At block 116, the example method 100 includes forming gate sidewall spacers on sidewalls of the dummy gate stack. Referring to the example of FIG. 8, in an embodiment of block 116, gate sidewall spacers 232 are formed on sidewalls of the sacrificial gate structure 224. The gate sidewall spacers 232 may include a dielectric material such as silicon oxide, silicon nitride, silicon carbide, silicon oxynitride, SiCN films, silicon oxycarbide, SiOCN films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

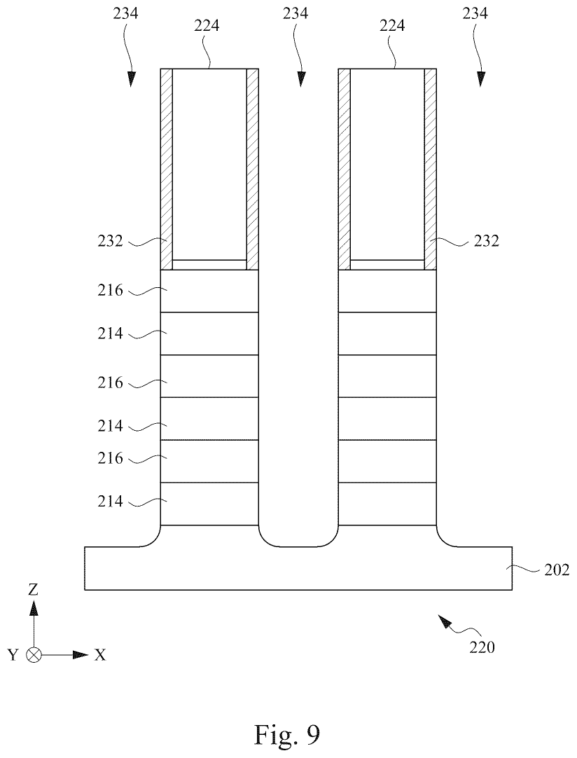

At block 118, the example method includes recessing the fins in the source drain/regions. Referring to the example of FIG. 9, in an embodiment of block 118, the fins in the source drain/regions are recessed. The stacked epitaxial layers 214 and 216 are etched down at the S/D regions to form a recess 234. A top portion of the substrate 202 is also etched. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF4, SF6, CH2F2, CHF3, and/or C2F6), other suitable gases, or combinations thereof.

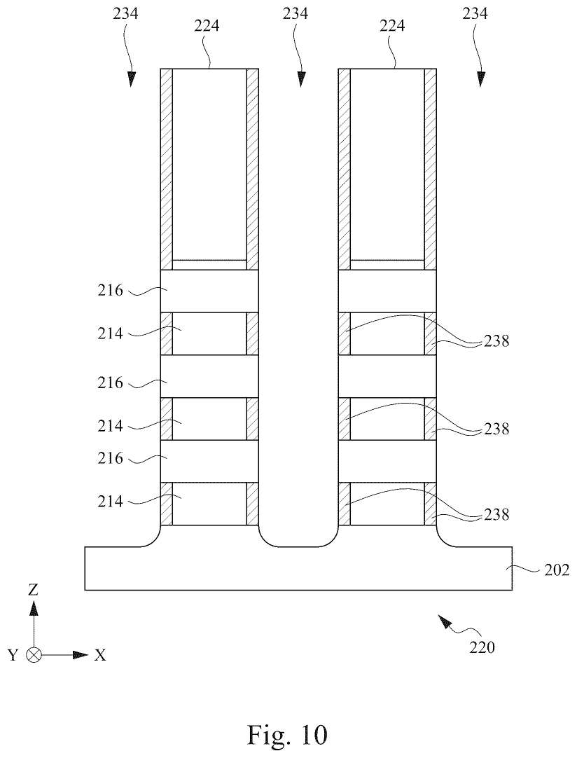

At block 120, the example method 100 Includes forming inner spacers. Forming inner spacers may include recessing sacrificial epitaxial layers (e.g., SiGe), depositing inner spacer material, and etching back inner spacer material. Referring to the example of FIG. 10, in an embodiment of block 120, inner spacers 238 are formed. The sacrificial epitaxial layers 214 have been etched back. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 120 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

As illustrated in the example of FIG. 10, the inner spacers 238 are formed on the lateral ends of the sacrificial epitaxial layers 214. This may be accomplished by forming an inner spacer material layer on the lateral ends of the sacrificial epitaxial layers 214 and the channel epitaxial layers 216 in the recess 234 followed by etching back the inner spacer material layer from the lateral ends of the channel epitaxial layers 216 and a portion of the inner spacer material layer from the lateral ends of the sacrificial epitaxial layers 214. The inner spacers 238 may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer. The inner spacer material layer can be formed by ALD or any other suitable method. After the inner spacer material layer is formed, an etching operation is performed to partially remove the inner spacer material layer.

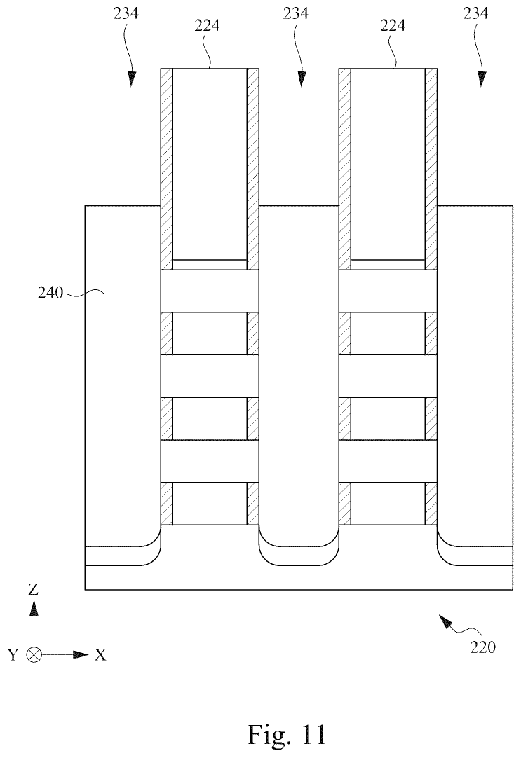

At block 122, the example method 100 includes forming source/drain (S/D) features. Referring to the example of FIG. 11, in an embodiment of block 122. Epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216, and separated from the sacrificial epitaxial layers 214 by the inner spacers 238.

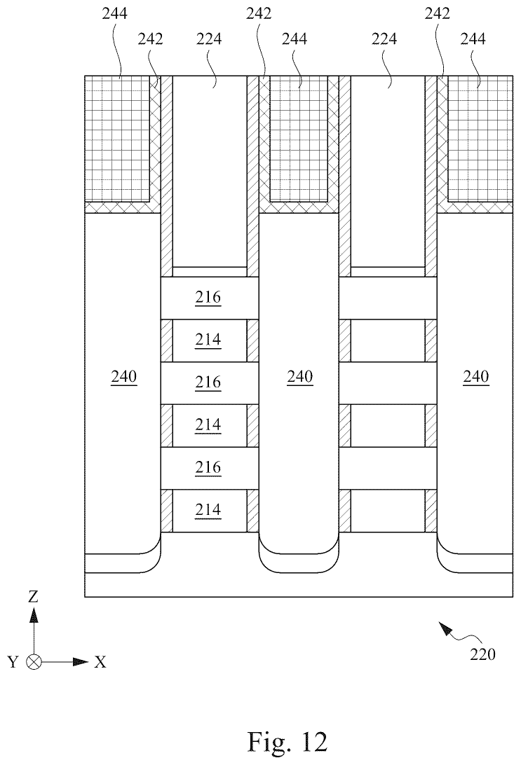

At block 124, the example method 100 includes forming CESL and ILD layers. Referring to the example of FIG. 12, in an embodiment of block 124, a contact etch stop layer (CESL) 242 is formed over the epitaxial S/D features 240 and an interlayer dielectric (ILD) layer 244 is formed over the CESL layer 242. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. The ILD layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be formed by PECVD, flowable CVD (FCVD), or other suitable methods. In some embodiments, forming the ILD layer 244 further includes performing a CMP process to planarize a top surface of the device 200, such that the top surfaces of the sacrificial gate structure 224 are exposed.

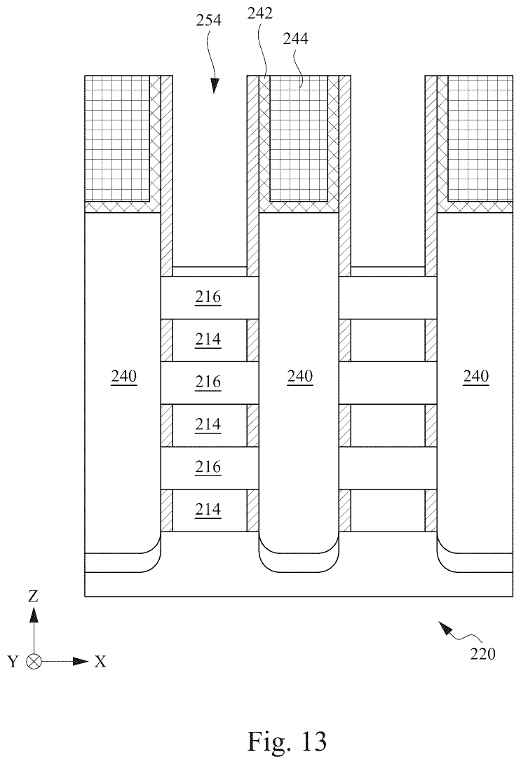

At block 126, the example method 100 includes removing the dummy gate stack to form a gate trench. Referring to the example of FIG. 13, in an embodiment of block 126, the sacrificial gate structure 224 has been removed to form a gate trench 254. The gate trench 254 exposes the fin 220 in the channel region(s). The ILD layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD layer 244 is an oxide, a wet etchant such as a TMAH solution can be used to selectively remove the sacrificial gate electrode layer. The sacrificial gate dielectric layer is thereafter removed using plasma dry etching and/or wet etching.

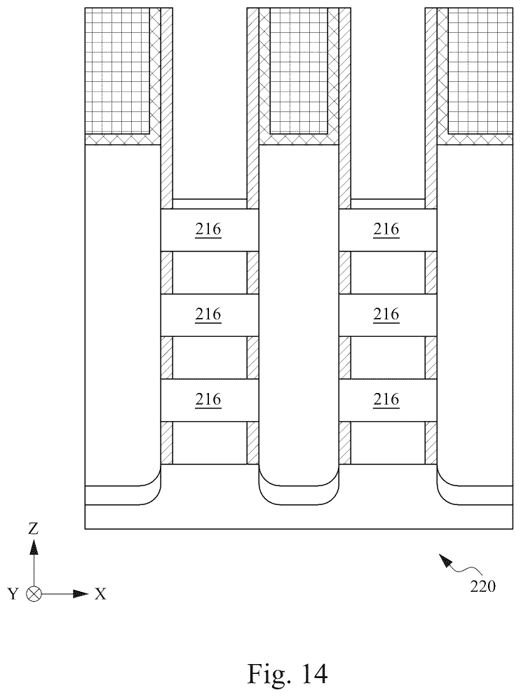

At block 128, the example method 100 includes removing the sacrificial epitaxial layers to form nanosheets. Referring to the example of FIG. 14, in an embodiment of block 128, sacrificial epitaxial layers have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

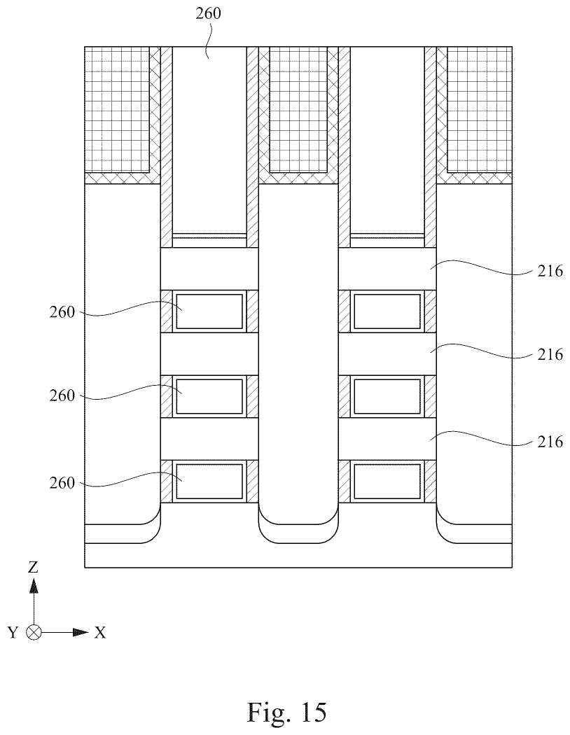

At block 130, the example method 100 includes forming high-K metal gate structures. Referring to the example of FIG. 15, in an embodiment of block 130, a gate structure 260 is formed. In various embodiments, the gate structure is the gate of a multi-gate transistor. In various embodiments, the gate structure is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layers. The high-K metal gate structures may include additional material layers.

At block 132, the example method 100 includes performing further fabrication. A semiconductor device may undergo further processing to form various features and regions known in the art. For example, subsequent processing may form contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

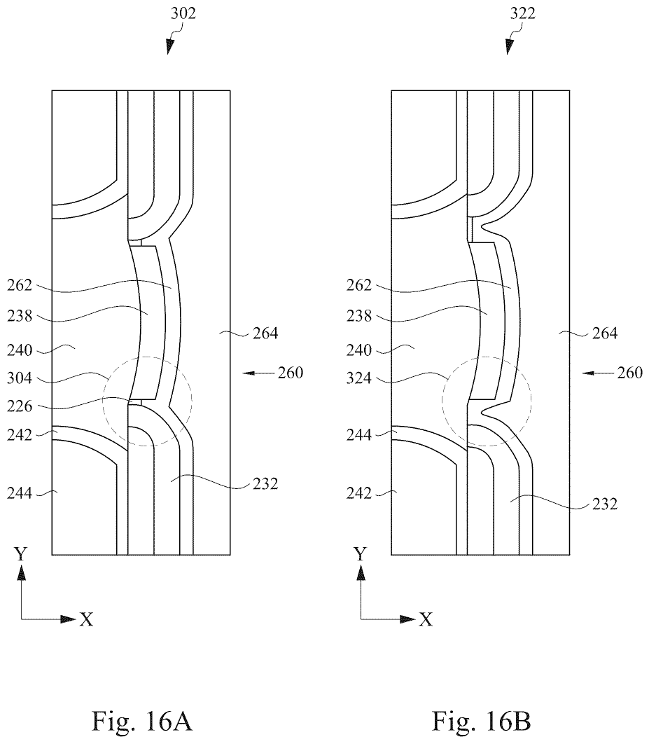

FIG. 16A is a schematic diagram providing a first plane view 302 and FIG. 16B is a schematic diagram providing an alternative plane view 322 of the gate structure of FIG. 15. The first plane view 302 depicts an example gate structure that can be formed using techniques described herein wherein the stop cap layer 222 was formed from SiON with a N concentration of 2-10%. The alternative plane view 322 depicts an alternate gate structure that may be formed when a stop cap layer 222 was not formed from SiON with a N concentration of 2-10%, but instead formed from SiO. Each of the first plane view 302 and the alternative plane view 322 includes a CESL layer 242, an ILD layer 244, gate sidewall spacers 232, inner spacers 238, S/D features 240, and gate structure 260 (e.g., a high-K metal gate stack with a gate dielectric layer that includes an interfacial layer 262 and a high-k dielectric layer 264).

Because the stop cap layer 222 was formed from SiON with a N concentration of 2-10%, a region 304 in the first plane view 302 includes the Nitride liner 226 (formed from the stop cap layer 222) between the S/D features 240, the gate structure 260, the inner spacers 238 and the gate sidewall spacers 232 to prevent shorting between the gate structure 260 and the S/D features 240. In contrast, in the alternative plane view 322, in which a stop cap layer was not formed from SiON with a N concentration of 2-10%, but instead formed from SiO, shorting between the gate structure 260 and the S/D features 240 may occur in a region 324.

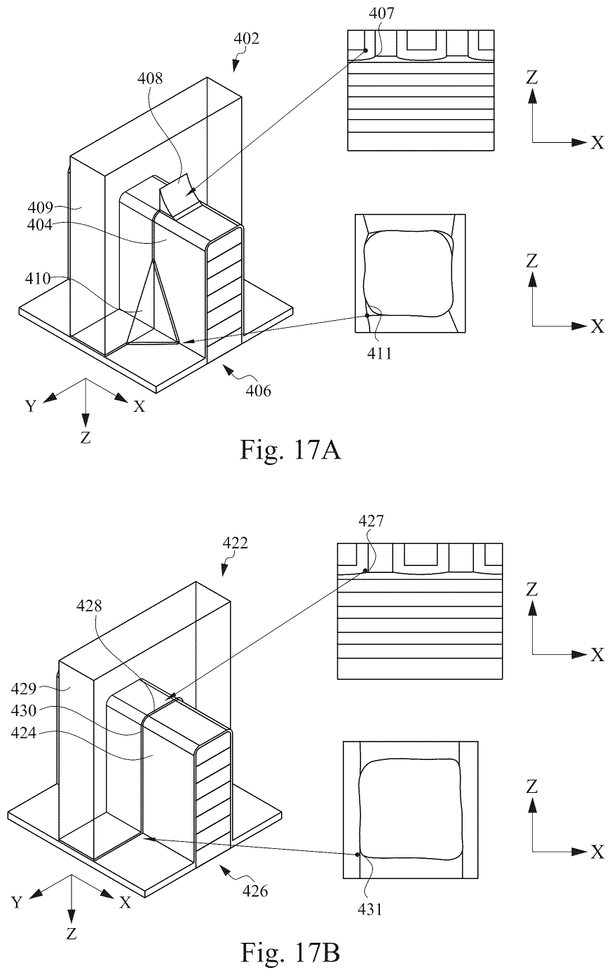

FIGS. 17A and 17B are schematic diagrams depicting example semiconductor structures 402, 422 after dummy gate patterning operations. In the example of FIG. 17A, a stop cap layer 404 was formed over the fin 406 of semiconductor structure 402 prior to dummy gate deposition. In this example, the stop cap layer 404 was formed from SiO. In this example, a nanosheet profile footing 408 was formed at the intersection 407 between the dummy gate 409 and top of the fin 406 after dummy gate patterning operations. Also, corner residue 410 remains at the bottom corner junction between the fin 406 and the dummy gate 409 after dummy gate patterning operations. FIG. 17A also shows that the nanosheet profile footing 408 results in a rounded corner at the intersection between the dummy gate 409 and top of the fin 406. Additionally, FIG. 17A shows that the corner residue 410 results in a non-perpendicular angle at the bottom corner junction 411 between the fin 406 and the dummy gate 409.

In the example of FIG. 17B, a stop cap layer 424 (such as stop cap layer 222) was formed over the fin 426 of semiconductor structure 422 prior to dummy gate deposition. In this example, the stop cap layer 424 was formed from SiON with a N concentration of 2-10%. In this example, due to the stop cap layer 424 formed from SiON with a N concentration of 2-10%, zero or minimal profile footing 428 can be detected. Also, zero or minimal corner residue 430 can be detected. FIG. 17B also shows the absence (or near absence) of nanosheet profile footing 428 and a square edge at the intersection 427 between the dummy gate 429 and top of the fin 426. Additionally, FIG. 17B shows that the absence (or near absence) of corner residue 430 results in a perpendicular angle at the bottom corner junction 431 between the fin 426 and the dummy gate 429.

The stop cap layer 424 has prevented or substantially eliminated the formation of dummy gate related defects, such as nanosheet profile footing formed at the intersection between the dummy gate 429 and top of the fin 426 and corner residue formed around the corner at which the bottom of the dummy gate 429 and the bottom of the fin 426 intersect. The prevention or substantial elimination of the dummy gate related defects allows for subsequently formed gate spacers and inner gate spacers to isolate the subsequently formed metal gate from the subsequently formed source/drain regions. Also, portions of the stop cap layer 424 cooperate with the subsequently formed gate spacers and inner gate spacers to isolate the subsequently formed metal gate from the subsequently formed source/drain regions.

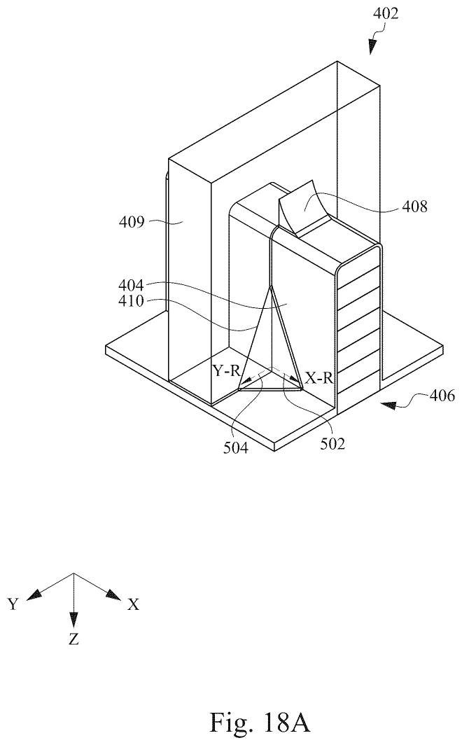

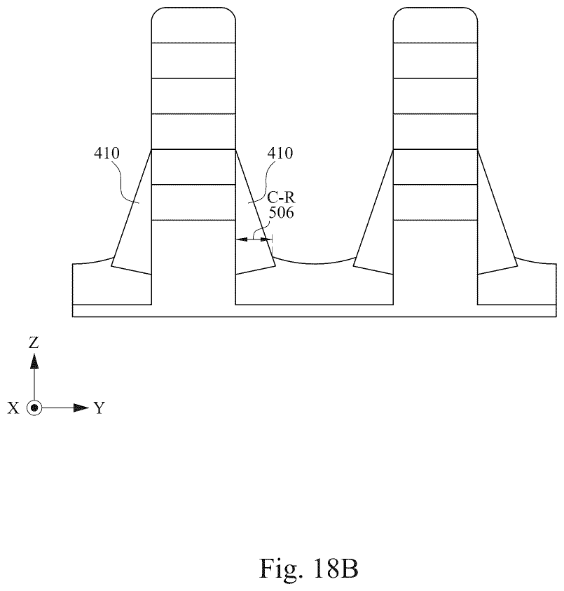

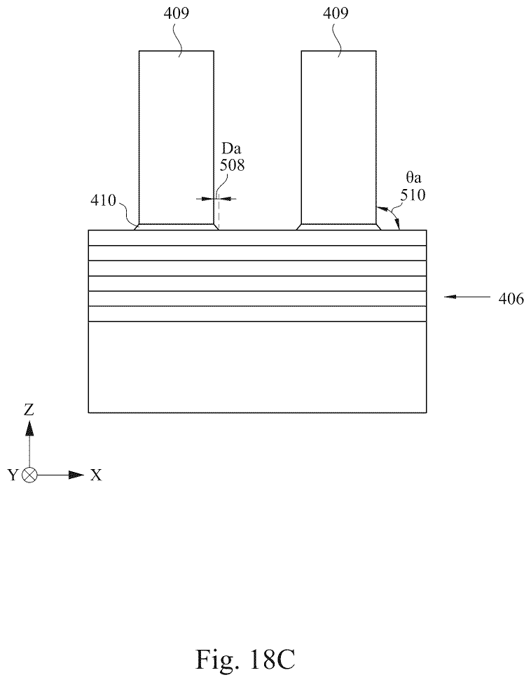

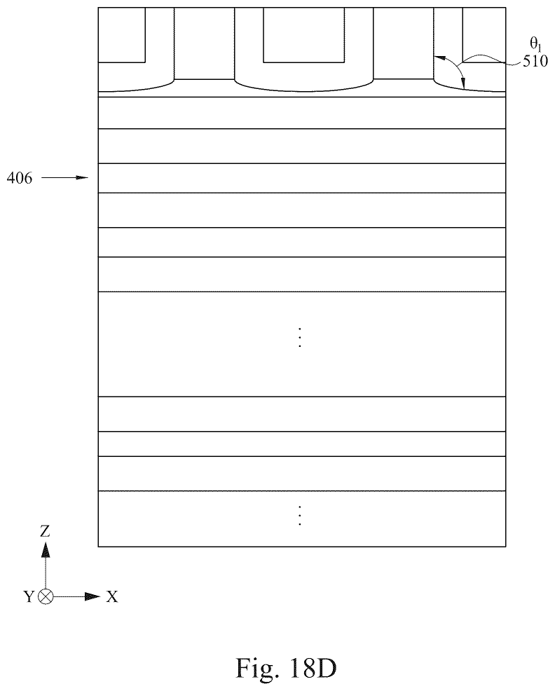

FIGS. 18A-18D are schematic diagrams illustrating example features of the nanosheet profile footing 408 and the corner residue 410 depicted in FIG. 17A. FIG. 18A illustrates that the corner residue 410 has an X-R dimension 502 in the X-direction, a Y-R dimension 504 in the Y-direction. In various embodiments, X-R=Y-R. In various embodiments, X-R=approximately 4 nm to approximately 9 nm. In various embodiments, X-R=approximately 4 nm to approximately 9 nm.

FIG. 18B illustrates that a cross-section of the semiconductor structure 402 along a plane in the Y-direction shows the corner residue 410 having a C-R dimension 506. In various embodiments, C-R=approximately 4 nm to approximately 9 nm.

FIG. 18C illustrates that the nanosheet profile footing 408 has a Da dimension 508 (e.g., of the Si from the dummy gate material plus stop layer material) and an θₐ angle 510 between the nanosheet profile footing 408 and the top of the fin. FIG. 18D also illustrates that the nanosheet profile footing 408 has an ea angle 510 between the nanosheet profile footing 408 and the top of the fin. In various embodiments, Da is between approximately 4 nm to approximately 9 nm. In various embodiments, 105°<θₐ<130°.

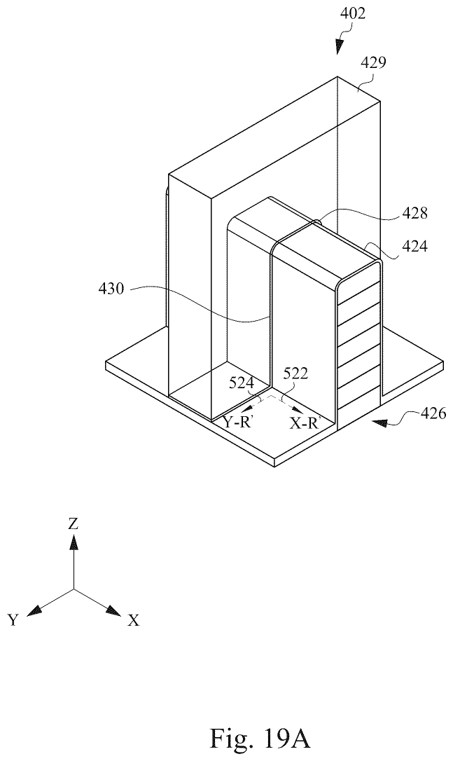

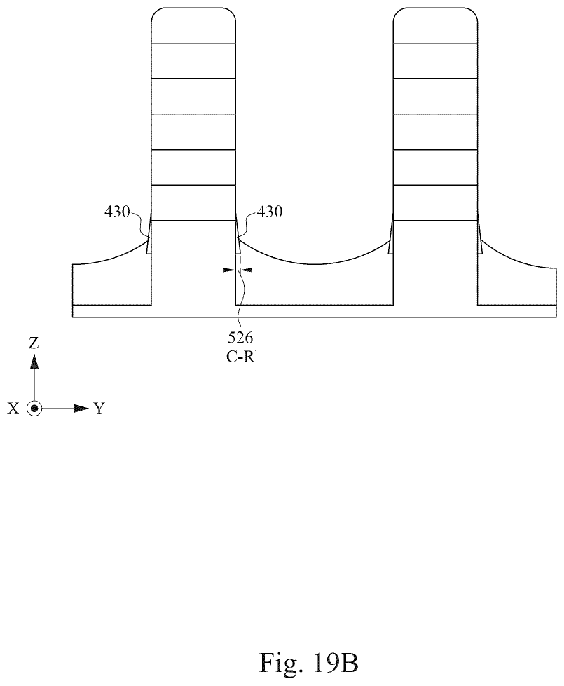

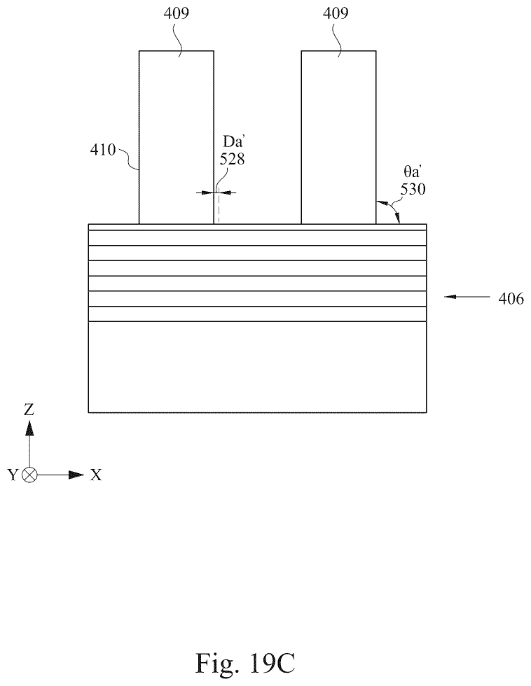

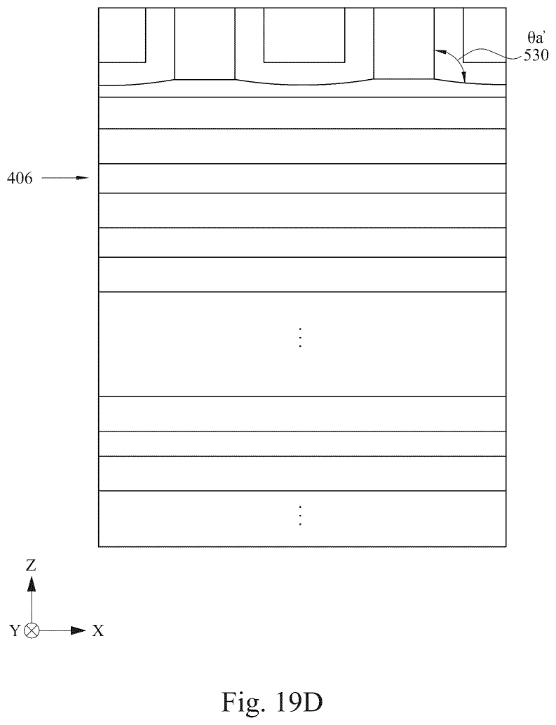

FIGS. 19A-19D are schematic diagrams illustrating example features of a near absence of nanosheet profile footing and a near absence of corner residue that can be achieved by using a stop cap layer 424 as depicted in FIG. 17B. Extra bottom Si/Oxide etching process that between dummy gate etching and stop-layer recess (remove more oxidation byproduct)

FIG. 19A illustrates that any corner residue 430 has an X-R′ dimension 522 in the X-direction, a Y-R′ dimension 524 in the Y-direction. In various embodiments, X-R′=Y-R′. In various embodiments, X-R′=between 0 nm to approximately 2 nm. In various embodiments, Y-R′=between 0 nm to approximately 2 nm. In various embodiments, Y-R′<2 nm.

FIG. 19B illustrates that a cross-section of the semiconductor structure 422 along a plane in the Y-direction shows the corner residue 430 having a C-R′ dimension 526. In various embodiments, C-R′=between 0 nm to approximately 2 nm. In various embodiments, C-R′<2 nm.

FIG. 19C illustrates that any nanosheet profile footing 428 has a Da′ dimension 528 and an θₐ′ angle 530 between the nanosheet profile footing 428 and the top of the fin. FIG. 19D also illustrates that the nanosheet profile footing 428 has an θₐ′ angle 530 between the nanosheet profile footing 428 and the top of the fin. In various embodiments, Da′ is between 0 nm to approximately 2 nm. In various embodiments, Da′<2 nm. In various embodiments, 90°<θₐ<100°.

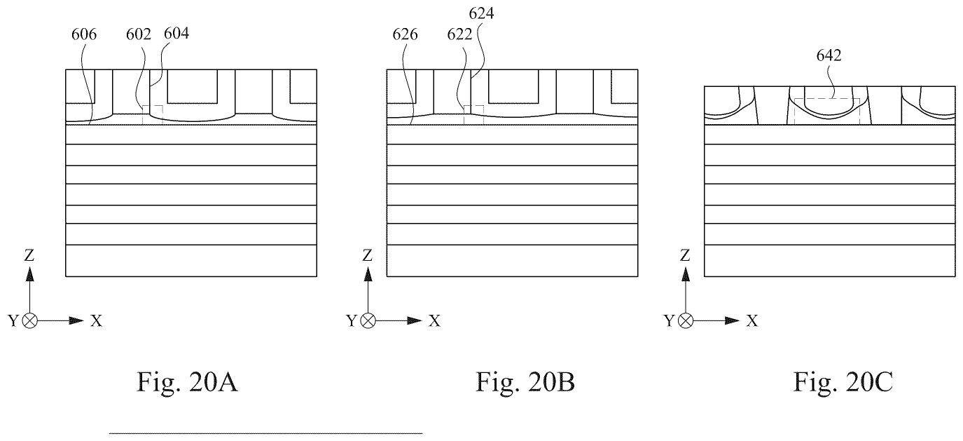

FIGS. 20A-20C illustrate example effects of including N in a stop layer formed from SiO. In the example of FIG. 20A, where a stop layer formed from SiOx with a N concentration of 0% had been used, a corner 602 between a side 604 of a dummy gate structure and a top side 606 of a fin structure is somewhat rounded. In the example of FIG. 20B, where a stop layer formed from SiON with a N concentration of between 2-10% has been used, a corner 622 between a side 624 of a dummy gate structure and a top side 626 of a fin structure is squarer. In the example of FIG. 20C, where a stop layer formed from SiON with a N concentration of between 15% or more has been used, a sheet pit 642 can develop which can damage a semiconductor device.

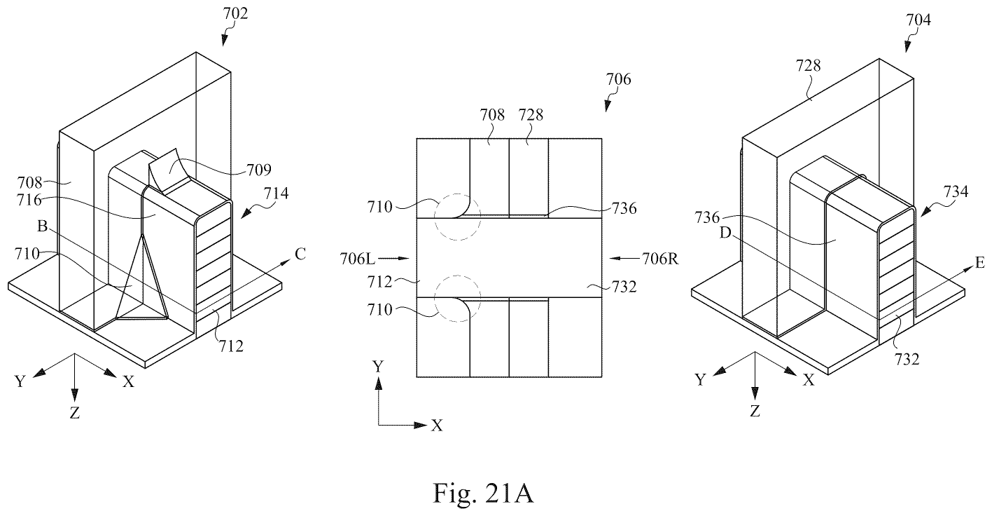

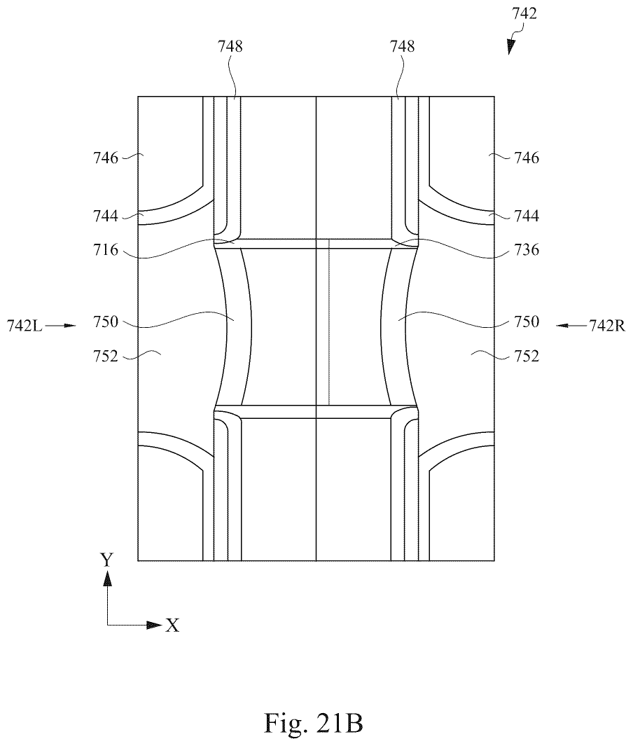

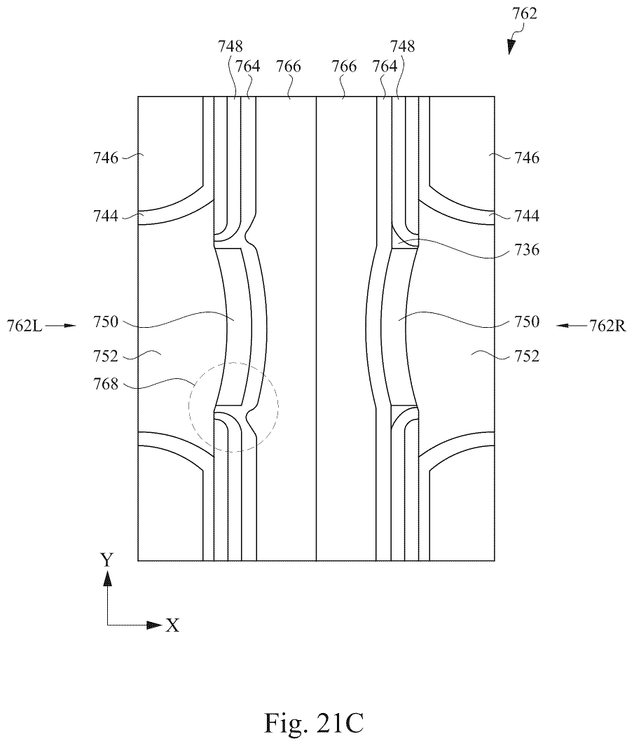

FIGS. 21A-21C are cross sectional views of semiconductor devices at various stages of fabrication. FIG. 21A depicts a semiconductor structure 702 after dummy gate patterning wherein a stop cap layer formed from SiOx with a N concentration of 0% had been used, and a semiconductor structure 704 after dummy gate patterning wherein a stop layer formed from SiON with a N concentration of 2-10% had been used. FIG. 21A also provides an example plane view 706 that depicts a plane view portion 706L of the semiconductor structure 702 along the cutline BC in the left half of plane view 706, and a plane view portion 706R of the semiconductor structure 704 along the cutline DE in the right half of plane view 706. Illustrated in the semiconductor structure 702 are a dummy gate material layer 708, corner residue 710, a sacrificial epitaxial layer 712 in a fin 714, and a stop cap layer 716 formed from SiOx with a N concentration of 0%. Illustrated in the plane view portion 706L are the dummy gate material layer 708, corner residue 710, and a sacrificial epitaxial layer 712. Illustrated in the semiconductor structure 704 are a dummy gate material layer 728, no corner residue, a sacrificial epitaxial layer 732 in a fin 734, and a stop cap layer 736 formed from SiON with a N concentration of 2-10%. Illustrated in the plane view portion 706R are the dummy gate material layer 728, no corner residue, a sacrificial epitaxial layer 732, and the stop cap layer 736.

FIG. 21B provides an example plane view 742 having a first plane view portion 742L and a second plane view portion 742R. The first plane view portion 742L, in the left half of plane view 742, depicts a portion of the semiconductor structure 702 along the cutline BC after S/D formation operations. The second plane view portion 742R, in the right half of plane view 742, depicts a portion of the semiconductor structure 704 along the cutline DE after S/D formation operations. Illustrated in the first plane view portion 742L are CESL 744, ILD 746, gate spacers 748, stop cap layer 716, inner spacers 750, S/D region 752, and sacrificial epitaxial layer 712. Illustrated in the second plane view portion 742R are CESL 744, ILD 746, gate spacers 748, stop cap layer 736, inner spacers 750, S/D region 752, and sacrificial epitaxial layer 712.

FIG. 21C provides an example plane view 762 having a first plane view portion 762L and a second plane view portion 762R. The first plane view portion 762L, in the left half of plane view 762, depicts a portion of the semiconductor structure 702 along the cutline BC after metal gate formation operations. The second plane view portion 762R, in the right half of plane view 762, depicts a portion of the semiconductor structure 704 along the cutline DE after metal gate formation operations. Illustrated in the first plane view portion 762L are the CESL 744, ILD 746, gate spacers 748, inner spacers 750, S/D region 752, and a metal gate structure including an interfacial layer 764 and a high-k dielectric layer 766. Illustrated in the second plane view portion 762R are the CESL 744, ILD 746, gate spacers 748, stop cap layer 736, inner spacers 750, S/D region 752, and the metal gate structure including the interfacial layer 764 and the high-k dielectric layer 766.

Because the semiconductor structure 704 included the stop cap layer 736 formed from SiON with a N concentration of 2-10%, defects such as corner residue 410 or nanosheet profile footing 428 were not formed during dummy gate pattering operations so that spacing between the subsequently formed gate spacers and inner spacers are not distorted. Moreover, any spacing between the subsequently formed gate spacers and inner spacers was blocked by the stop cap layer 736 during metal gate formation operations. Thus, the use of the stop cap layer 736 formed from SiON with a N concentration of 2-10% prevents a short from occurring between the metal gate and the S/D region 752. In contrast, the stop cap layer 716 formed from SiOx with a N concentration of 0% allowed the formation of defects such as nanosheet profile footing 709 and corner residue 710 during dummy gate pattering operations thereby distorting spacing between the subsequently formed gate spacers 748 and inner spacers 750, which in turn may lead to a short forming between the subsequently formed metal gate and the S/D region 752 as illustrated in area 768.

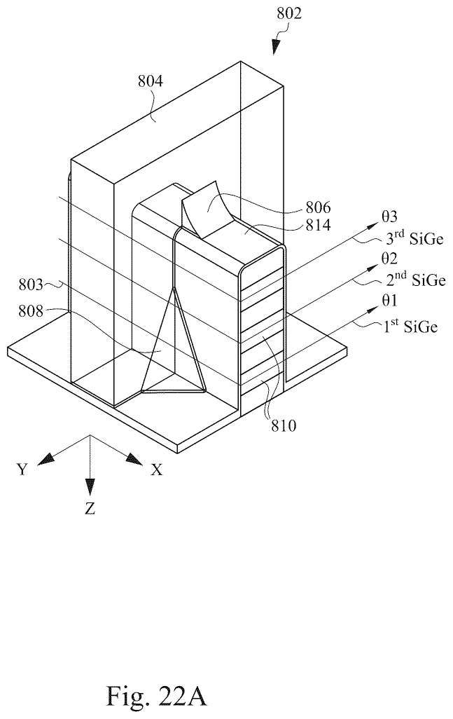

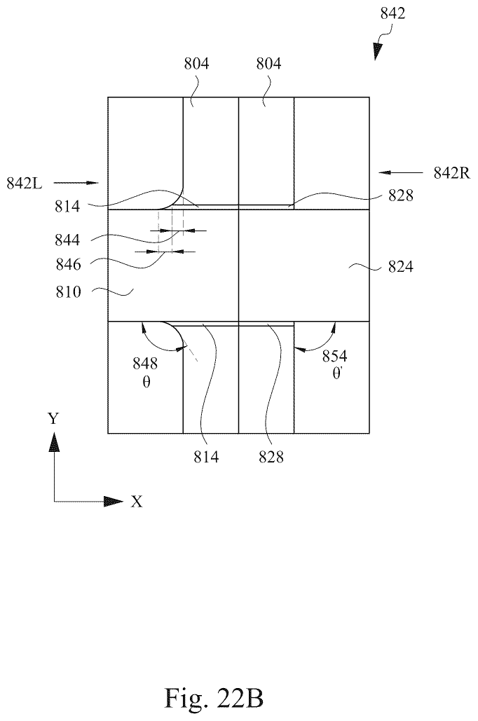

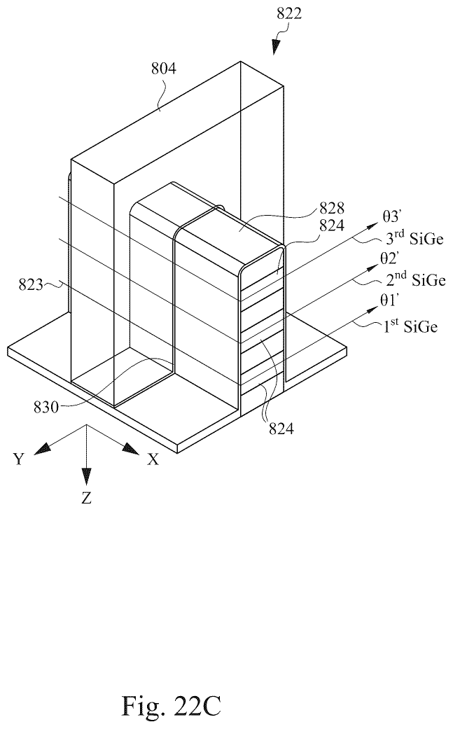

FIGS. 22A-22C are cross sectional views of semiconductor devices at a stage of fabrication after dummy gate patterning. FIG. 22A depicts a semiconductor structure 802 after dummy gate patterning wherein a stop cap layer formed from SiOx with a N concentration of 0% had been used. FIG. 22C depicts a semiconductor structure 822 after dummy gate patterning wherein a stop layer formed from SiON with a N concentration of 2-10% had been used. FIG. 22B provides an example plane view 842 that depicts a plane view portion 842L in the left half of plane view 842 of the semiconductor structure 802 along a first cutline 803, and a plane view portion 842R of the semiconductor structure 822 along a second cutline 823 in the right half of plane view 842. Illustrated in the semiconductor structure 802 are a dummy gate material layer 804, nano sheet profile footing 806, corner residue 808, a plurality of sacrificial epitaxial layers 810 in a fin, and a stop cap layer 814 formed from SiOx with a N concentration of 0%. Illustrated in the plane view portion 842L are the dummy gate material layer 804, corner residue 808, and a sacrificial epitaxial layer 810. Illustrated in the semiconductor structure 822 are a dummy gate material layer 804, no nano sheet profile footing or minimal corner residue 830, a sacrificial epitaxial layer 824 in a fin, and a stop cap layer 828 formed from SiON with a N concentration of 2-10%. Illustrated in the plane view portion 842R are the dummy gate material layer 804, zero or negligible corner residue, a sacrificial epitaxial layer 824, and the stop cap layer 828.

FIGS. 22A-22C illustrate that each of the sacrificial epitaxial layers 810 in the semiconductor structure 802 may have a defect in the form of corner residue 808 with unique dimensions. When a stop cap layer 828 formed from SiON with a N concentration of 2-10% is fabricated, nano sheet profile footing or corner residue 830 associated with a sacrificial epitaxial layer 824 in the semiconductor structure 822 may be non-existent or near zero. FIG. 22B illustrates example dimensions of the corner residue 808 and corner residue 830. The corner residue 808 has a first dimension B1 (844) measured from a beginning of the deformity in dummy gate material layer 804 to a beginning of the deformity in the stop cap layer 814, and a second dimension B2 (846) measured from the beginning of the deformity in stop cap layer 814 to an end of the deformity in the stop cap layer 814 that is adjacent to an associated sacrificial epitaxial layer 810. The corner residue 808 also has an angle θ (848) between a side of an associated sacrificial epitaxial layer 810 and an edge of the stop cap layer 814. The first dimension B1 (844), second dimension B2 (846), and angle θ (848) are different for each sacrificial epitaxial layer 810.

The corner residue 830 has a first dimension B1′ (852) measured from a beginning of the deformity in dummy gate material layer 804 to an end of the deformity in the stop cap layer 828 that is adjacent to an associated sacrificial epitaxial layer 824. The corner residue 830 also has an angle θ′ (854) between a side of an associated sacrificial epitaxial layer 824 and an edge of the stop cap layer 828. The first dimension B1′ (852) and angle θ′ (854) are different for each sacrificial epitaxial layer 824.

In various embodiments, B1′ (which has more process window)<B1, B2 (which can yield a MD-MG short). B2, B1 dimensions can induce EPI damage, MG extrusion, and MG-MD short. In various embodiments, the B1 critical dimension is approximately 2.5 to approximately 6.5 nm, the B2 critical dimension is approximately 1.5 to approximately 2.5 nm, and the B1′ critical dimension is approximately 0 to 2 nm.

In various embodiments, Θ′<Θ. If Θ angle is enlarged, it can induce extrusion and metal gate short. In various embodiments, Θ1′=90 to approximately 100°; Θ2′=90 to approximately 96°; Θ3′=90 to approximately 93°; Θ1=105 to approximately 130°, Θ2=100 to approximately 120°, and Θ3, =95 to approximately 110°. The closer Θ1′, Θ2′, and Θ3′ are to 90° the less likely there will be metal gate extrusion and metal gate short.

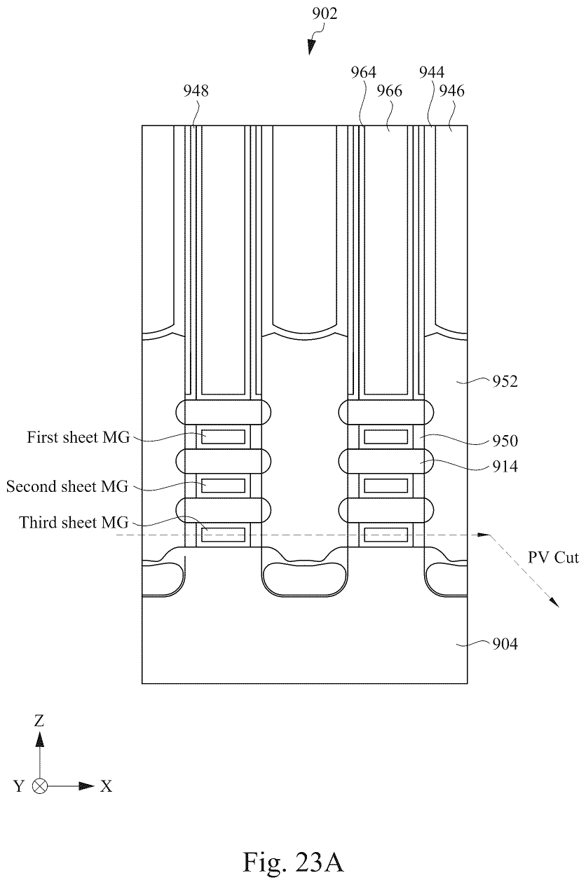

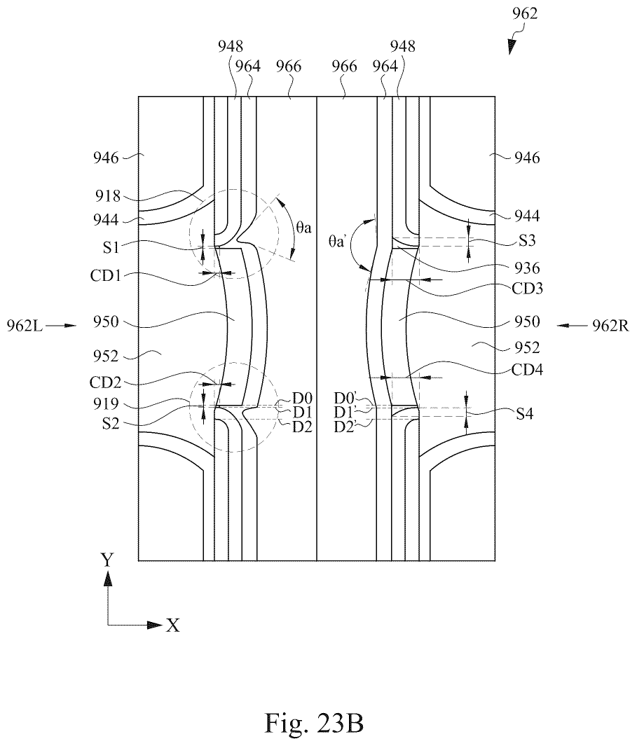

FIG. 23A depicts a cross sectional view of a portion of a fin 902 of semiconductor structure at a stage of fabrication after replacement metal gate formation. Illustrated are a substrate 904, channel regions (e.g., nanosheets) 914, CESL 944, ILD 946, gate spacers 948, inner spacers 950, S/D region 952, and a metal gate structure including an interfacial layer 964 and a high-k dielectric layer 966.

FIG. 23B provides an example plane view 962 having a first plane view portion 962R and an alternate plane view portion 962L. The first plane view portion 962R, in the right half of plane view 962, depicts a portion of the fin 902 along the cutline PV after metal gate formation operations when a stop cap layer with a N concentration of approximately 2 to 10% was applied prior to dummy gate fabrication. The alternate plane view portion 962L, in the Left half of plane view 962, depicts a portion of the fin 902 along the cutline PV after metal gate formation operations when a stop cap layer with a N concentration of approximately 2 to 10% was not applied prior to dummy gate fabrication. Illustrated in both the first plane view portion 962R and the alternate plane view portion 962L are the CESL 944, ILD 946, gate spacers 948, inner spacers 950, Nitride liner 936 formed from a stop cap layer with a N concentration of approximately 2 to 10%, S/D region 952, and a metal gate structure including an interfacial layer 964 and a high-k dielectric layer 966.

In the alternate plane view portion 962L, the gate spacer 948 and the inner spacer 950 may form with a first gap S1, a second gap S2, a first critical dimension stop layer CD1, and a second critical dimension stop layer CD2. The first gap S1 and second gap S2 depict gaps that may form between the gate spacer 948 and the inner spacer 950 during fabrication. The first critical dimension stop layer CD1, and the second critical dimension stop layer CD2 depict gaps that may form between the S/D region 952 and the interfacial layer 964 of the metal gate. The alternate plane view portion 962L further includes a first curvature angle θa that is defined in the interfacial layer 964 of the metal gate around a border between the gate spacer 948 and the inner spacer 950. The alternate plane view portion 962L further includes a first inner spacer distance D1 to DO that is defined between an end of the inner spacer 950 to an end of spacer1 of the inner spacer 948. The alternate plane view portion 962L further includes a second inner spacer distance D2 to D0 that is defined between an end of the inner spacer 950 to an end of spacer2 of the inner spacer 948. The alternate plane view portion 962L also includes areas 918, 919 where EPI damage may occur due to the dimensions of the first gap S1, second gap S2, first critical dimension CD1, and second critical dimension CD2. In this example, S1 and S2 are too large and the critical dimension of the stop layers CD1 and CD2 are too small. Short circuits between the metal drain in S/D region 952 and the interfacial layer 964 of the metal gate may occur in the areas 918, 919 due to insufficient separation provided by the gate spacer 948 and inner spacer 950.

In the first plane view portion 962R, the gate spacer 948 and the inner spacer 950 may form with a third gap S3, a fourth gap S4, a third critical dimension stop layer CD3, and a fourth critical dimension stop layer CD4. The third gap S3 and fourth gap S4 depict gaps that may form between the gate spacer 948 and the inner spacer 950 during fabrication. The third critical dimension stop layer CD3, and the fourth critical dimension stop layer CD4 depict gaps that may form between the S/D region 952 and the interfacial layer 964 of the metal gate. The first plane view portion 962R further includes a first curvature angle θa′ that is defined in the interfacial layer 964 of the metal gate around a border between the gate spacer 948 and the inner spacer 950. The first plane view portion 962R further includes a first inner spacer distance D1′ to DO′ that is defined between an end of the inner spacer 950 to an end of spacer1 of the inner spacer 948. The first plane view portion 962R further includes a second inner spacer distance D2′ to DO′ that is defined between an end of the inner spacer 950 to an end of spacer2 of the inner spacer 948. The first plane view portion 962R does not include areas where EPI damage may occur due to the dimensions of the third gap S3, fourth gap S4, third critical dimension CD3, and fourth critical dimension CD4. In this example, S3, S4, CD3, and CD4 are sufficient. Short circuits between the metal drain in the S/D region 952 and the interfacial layer 964 of the metal gate should not occur (e.g., probability of occurrence is close to 0%) because the gate spacer 948 and inner spacer 950 provide sufficient separation. The third gap S3 and fourth gap S4 between the gate spacer 948 and the inner spacer 950 are small enough to prevent a short circuit between the interfacial layer 964 of the metal gate and the metal drain in the S/D region 952. The third critical dimension stop layer CD3, and the fourth critical dimension stop layer CD4 formed by the gate spacer 948 and the inner spacer 950 is large enough to prevent a short circuit between the interfacial layer 964 of the metal gate and the metal drain in the S/D region 952.

In various embodiments, CD3 is equal to or approximately equal to CD4, and both CD3 and CD4 are greater than both CD1 and CD2. In various embodiments, CD1 and CD2 are approximately 0.3 nm (nanometer) to approximately 3 nm, whereas CD3 and CD4 have a thicker block wall of approximately 5 nm to approximately 10 nm.

In various embodiments, S2≥S1 and both (S2 and S1)>S4≥S3. In various embodiments, S1 and S2 are approximately 3 nm to approximately 5 nm. In various embodiments, S3 and S4 are approximately 0.3 to approximately 1 nm. In various embodiments, S3 and S4 are less than 1 nm.

In various embodiments, for the bottom sheet MG position, θa′ is approximately 150° to approximately 165° and θa is approximately 80° to approximately 100°. In various embodiments, for the middle sheet MG position, θa′ is approximately 165° to approximately 170° and Ba is approximately 100° to approximately 130°. In various embodiments, for the first sheet MG position, θa′ is approximately 170° to approximately 180° and θa is approximately 160° to approximately 180°. If the semiconductor device has more than three nanosheets, then θa′ is approximately 160° to approximately 180°, whereas θa is approximately 160° to approximately 180°.

In various embodiments, the first inner spacer distance D1′ to D0′ is approximately 0.3 nm to approximately 1 nm. In various embodiments, the second inner spacer distance D2′ to D0′ is approximately 5 nm to approximately 8 nm. In various embodiments, the first inner spacer distance D1 to D0 is approximately 3 nm to approximately 5 nm. In various embodiments, the second inner spacer distance D2 to D0 is approximately 8 nm to approximately 13 nm.

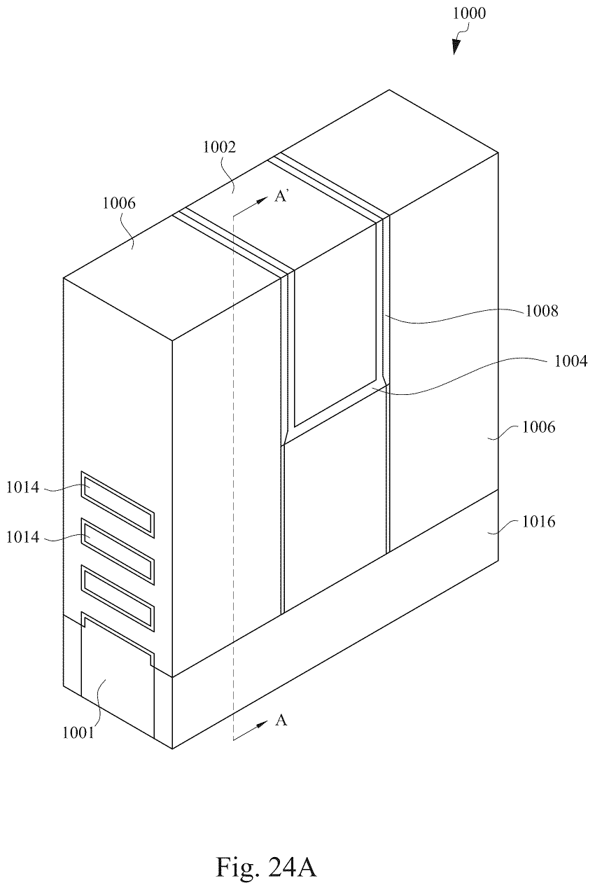

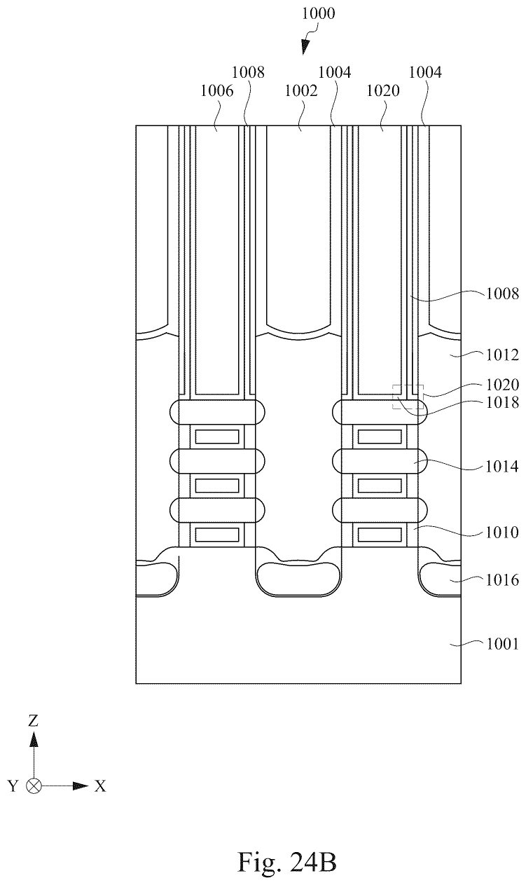

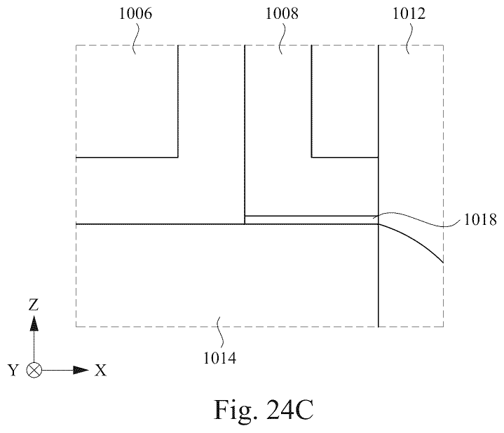

FIG. 24A is a three-dimensional schematic diagram of a portion of a fin 1000 of an example semiconductor device formed with features described herein. FIG. 24B provides a cross-sectional view of the fin 1000 of FIG. 24A along a cutline A-A′. The example fin 1000 includes a substrate 1001, an interlayer dielectric (ILD) 1002, a contact etch stop layer (CESL) 1004, a high-K metal gate 1006, a gate spacer 1008, an inner spacer 1010, an S/D epitaxial region 1012, channel regions 1014 (e.g., nanosheets), STI 1016, and a Nitride liner 1018 (e.g., SiCN, SiOCN, SiON). The high-K material of the high-K metal gate 1006 may include HfO, TaN, or other suitable material. The metal of the high-K metal gate 1006 may include W, Cu, Co, or other suitable materials. The gate spacer 1008 may be formed from SiCN, SiOCN, SiON, SIN, or other suitable materials. The inner spacer 1010 may be formed from SiCN, SiOCN, SiON, SIN, or other suitable materials. The Nitride liner 1018 may result from a stop cap layer being formed prior to sacrificial gate electrode layer fabrication and dummy gate patterning. The stop cap layer may have been formed from a Nitride, such as SiCN, SiOCN, or SiON wherein the concentration of N in the Nitride is 2 to 10%.

FIG. 24C provides a cross-sectional view of a portion of the fin 1000 that is depicted in area 1020 of FIG. 24B. The view illustrates the high-K metal gate 1006, gate spacer 1008, an S/D epitaxial region 1012, channel region 1014, and a Nitride liner 1018 (e.g., SiCN, SiOCN, SiON) that separates the high-K metal gate 1006 from the S/D epitaxial region 1012.

Improved systems, fabrication methods, fabrication techniques, and articles have been described. The described systems, methods, techniques, and articles can be used with a wide range of semiconductor devices including Gate-all-around FET (GAAFET/NSFET)/Fork-sheet/CFET/VFET/MOSFET.

In some aspects, the techniques described herein relate to a fabrication method, including: forming, on a substrate, an epitaxial stack including at least one sacrificial epitaxial layer and at least one channel epitaxial layer; forming a plurality of fins in the epitaxial stack; forming a stop cap layer over the plurality of fins and substrate, the stop cap layer formed with a substantial concentration of nitrogen (N); forming a sacrificial gate stack on channel regions of the plurality of fins; removing the sacrificial gate stack and sacrificial epitaxial layer; and forming a metal gate, wherein the metal gate is shielded from source/drain features by a gate sidewall spacer, an inner spacer, and a first liner formed from the stop cap layer.

In some aspects, the techniques described herein relate to a fabrication method, wherein the first liner includes SiCN, SiOCN, or SiON.

In some aspects, the techniques described herein relate to a fabrication method, wherein the first liner has a concentration of N greater than or equal to 2%.

In some aspects, the techniques described herein relate to a fabrication method, wherein the first liner has a concentration of N of between 2% and 10%.

In some aspects, the techniques described herein relate to a fabrication method, wherein the first liner has a concentration of N of between 7% and 8%.

In some aspects, the techniques described herein relate to a fabrication method, wherein forming the sacrificial gate stack includes forming a corner residue deformity between a side of the epitaxial stack and a side of the sacrificial gate stack that has angle between a side of a lowest sacrificial epitaxial layer in the epitaxial stack and an edge of the stop cap layer that is between 90° and 100°.

In some aspects, the techniques described herein relate to a fabrication method, wherein forming the sacrificial gate stack includes forming a corner residue deformity between a side of the epitaxial stack and a side of the sacrificial gate stack that has angle between a side of a second lowest sacrificial epitaxial layer in the epitaxial stack and an edge of the stop cap layer that is between 90° and 96°.

In some aspects, the techniques described herein relate to a fabrication method, wherein forming the sacrificial gate stack includes forming a corner residue deformity between a side of the epitaxial stack and a side of the sacrificial gate stack that has a curvature angle between a side of a third lowest sacrificial epitaxial layer in the epitaxial stack and an edge of the stop cap layer that is between 90° and 93°.

In some aspects, the techniques described herein relate to a fabrication method, wherein forming the sacrificial gate stack includes forming a corner residue deformity between a side of the epitaxial stack and a side of the sacrificial gate stack that has a dimension measured from the sacrificial gate stack to a sacrificial epitaxial layer in the sacrificial gate stack that is less than 2 nm.

In some aspects, the techniques described herein relate to a fabrication method, wherein forming the metal gate includes forming the metal gate with a gap between the gate sidewall spacer and the inner spacer of less than 3 nm.

In some aspects, the techniques described herein relate to a fabrication method, wherein forming the metal gate includes forming the metal gate with a gap between the gate sidewall spacer and the inner spacer of less than 1 nm.

In some aspects, the techniques described herein relate to a fabrication method, wherein forming the metal gate includes forming the metal gate with a gap between the gate sidewall spacer and the inner spacer of 0.3 nm to 1 nm.

In some aspects, the techniques described herein relate to a fabrication method, wherein forming the metal gate includes forming the metal gate with a first critical dimension stop layer gap between a source/drain (S/D) region and an interfacial layer of the metal gate of greater than 3 nm.

In some aspects, the techniques described herein relate to a fabrication method, wherein forming the metal gate includes forming the metal gate with a first critical dimension stop layer gap between a source/drain (S/D) region and an interfacial layer of the metal gate of greater than 5 nm.

In some aspects, the techniques described herein relate to a fabrication method, wherein forming the metal gate includes forming the metal gate with a first critical dimension stop layer gap between a source/drain (S/D) region and an interfacial layer of the metal gate between 5 nm to 10 nm.

In some aspects, the techniques described herein relate to a fabrication method, wherein forming the metal gate includes forming a first inner spacer distance of between 0.3 nm to 1 nm that is defined between an end of an inner spacer to an end of a first spacer of the inner spacer, and a second inner spacer distance of between 5 nm to 8 nm that is defined between the end of the inner spacer to an end of a second spacer of the inner spacer.

In some aspects, the techniques described herein relate to a fabrication method, wherein forming the metal gate includes forming a first inner spacer distance less than 3 nm that is defined between an end of an inner spacer to an end of a first spacer of the inner spacer, and a second inner spacer distance less than 8 nm that is defined between the end of the inner spacer to an end of a second spacer of the inner spacer.

In some aspects, the techniques described herein relate to a fabrication method, wherein forming the metal gate includes forming a first inner spacer distance less than 1 nm that is defined between an end of an inner spacer to an end of a first spacer of the inner spacer, and a second inner spacer distance less than 8 nm that is defined between the end of the inner spacer to an end of a second spacer of the inner spacer.

In some aspects, the techniques described herein relate to a fabrication method, wherein forming the metal gate includes a first curvature angle of between 150° to 165° that is defined in an interfacial layer of the metal gate around a border between a gate sidewall spacer and an inner spacer for a lowest sacrificial epitaxial layer in the epitaxial stack.

In some aspects, the techniques described herein relate to a fabrication method, wherein forming the metal gate includes a first curvature angle of greater than 100° that is defined in an interfacial layer of the metal gate around a border between a gate sidewall spacer and an inner spacer for a lowest sacrificial epitaxial layer in the epitaxial stack.

In some aspects, the techniques described herein relate to a fabrication method, wherein forming the metal gate includes a second curvature angle of between 165° to 170° that is defined in an interfacial layer of the metal gate around a border between a gate sidewall spacer and an inner spacer for a second lowest sacrificial epitaxial layer in the epitaxial stack.

In some aspects, the techniques described herein relate to a fabrication method, wherein forming the metal gate includes a second curvature angle of greater than 130° that is defined in an interfacial layer of the metal gate around a border between a gate sidewall spacer and an inner spacer for a second lowest sacrificial epitaxial layer in the epitaxial stack.

In some aspects, the techniques described herein relate to a fabrication method, wherein forming the metal gate includes a third curvature angle of between 170° to 180° that is defined in an interfacial layer of the metal gate around a border between a gate sidewall spacer and an inner spacer for a third lowest sacrificial epitaxial layer in the epitaxial stack.

In some aspects, the techniques described herein relate to a semiconductor structure, including: a fin including a plurality of nanosheets disposed over a substrate; a gate structure disposed over a channel region of the plurality of nanosheets; and a first liner formed in a gap between a gate sidewall spacer and an inner spacer, wherein the gate sidewall spacer, the inner spacer, and the first liner shield the gate structure from source/drain (S/D) features.

In some aspects, the techniques described herein relate to a semiconductor structure, wherein the first liner includes SiCN, SiOCN, or SiON.

In some aspects, the techniques described herein relate to a semiconductor structure, wherein the first liner has a concentration of N of between 2% and 10%.

In some aspects, the techniques described herein relate to a semiconductor structure, wherein the first liner has a concentration of N of between 7% and 8%.

In some aspects, the techniques described herein relate to a semiconductor structure, wherein the gap between the gate sidewall spacer and the inner spacer is less than 3 nm.

In some aspects, the techniques described herein relate to a semiconductor structure, wherein the gap between the gate sidewall spacer and the inner spacer is less than 1 nm.

In some aspects, the techniques described herein relate to a semiconductor structure, wherein the gap between the gate sidewall spacer and the inner spacer is 0.3 nm to 1 nm.

In some aspects, the techniques described herein relate to a semiconductor structure, wherein a first critical dimension stop layer gap between a source/drain (S/D) region and an interfacial layer of the gate structure is greater than 3 nm.

In some aspects, the techniques described herein relate to a semiconductor structure, wherein a first critical dimension stop layer gap between a source/drain (S/D) region and an interfacial layer of the gate structure is greater than 5 nm.

In some aspects, the techniques described herein relate to a semiconductor structure, wherein a first critical dimension stop layer gap between a source/drain (S/D) region and an interfacial layer of the gate structure is between 5 nm to 10 nm.

In some aspects, the techniques described herein relate to a semiconductor structure, wherein a first inner spacer distance of between 0.3 nm to 1 nm is defined between an end of an inner spacer to an end of a first spacer of the inner spacer, and a second inner spacer distance of between 5 nm to 8 nm is defined between the end of the inner spacer to an end of a second spacer of the inner spacer.

In some aspects, the techniques described herein relate to a semiconductor structure, wherein a first inner spacer distance of less than 3 nm is defined between an end of an inner spacer to an end of a first spacer of the inner spacer, and a second inner spacer distance less than 8 nm that is defined between the end of the inner spacer to an end of a second spacer of the inner spacer.

In some aspects, the techniques described herein relate to a semiconductor structure, wherein a first inner spacer distance of less than 1 nm is defined between an end of an inner spacer to an end of a first spacer of the inner spacer, and a second inner spacer distance less than 8 nm that is defined between the end of the inner spacer to an end of a second spacer of the inner spacer.

In some aspects, the techniques described herein relate to a semiconductor structure, wherein the fin includes an epitaxial stack and a first curvature angle of between 150° to 165° is defined in an interfacial layer of the gate structure around a border between a gate sidewall spacer and an inner spacer for a lowest sacrificial epitaxial layer in the epitaxial stack.

In some aspects, the techniques described herein relate to a semiconductor structure, wherein the fin includes an epitaxial stack and a first curvature angle of greater than 100° is defined in an interfacial layer of the gate structure around a border between a gate sidewall spacer and an inner spacer for a lowest sacrificial epitaxial layer in the epitaxial stack.

In some aspects, the techniques described herein relate to a semiconductor structure, wherein the fin includes an epitaxial stack and a second curvature angle of between 165° to 170° is defined in an interfacial layer of the gate structure around a border between a gate sidewall spacer and an inner spacer for a second lowest sacrificial epitaxial layer in the epitaxial stack.

In some aspects, the techniques described herein relate to a semiconductor structure, wherein the fin includes an epitaxial stack and a second curvature angle of greater than 130° is defined in an interfacial layer of the gate structure around a border between a gate sidewall spacer and an inner spacer for a second lowest sacrificial epitaxial layer in the epitaxial stack.

In some aspects, the techniques described herein relate to a semiconductor structure, wherein the fin includes an epitaxial stack and a third curvature angle of between 170° to 180° is defined in an interfacial layer of the gate structure around a border between a gate sidewall spacer and an inner spacer for a third lowest sacrificial epitaxial layer in the epitaxial stack.

In some aspects, the techniques described herein relate to a fabrication method, including: depositing a stop cap layer over a fin having an epitaxial stack, the stop cap layer including a concentration of at least 2% nitrogen (N); forming a sacrificial gate stack on channel regions of the fin; and replacing the sacrificial gate stack and a sacrificial epitaxial layer of the fin with a metal gate, wherein the metal gate is shielded from source/drain features by a gate sidewall spacer, an inner spacer, and a first liner formed from the stop cap layer.

In some aspects, the techniques described herein relate to a fabrication method, wherein the first liner includes SiCN, SiOCN, or SiON.

In some aspects, the techniques described herein relate to a fabrication method, wherein the first liner has a concentration of N of between 2% and 10%.

In some aspects, the techniques described herein relate to a fabrication method, wherein the first liner has a concentration of N of between 7% and 8%.

In some aspects, the techniques described herein relate to a fabrication method, wherein forming the sacrificial gate stack includes forming a corner residue deformity between a side of the epitaxial stack and a side of the sacrificial gate stack that has angle between a side of a lowest sacrificial epitaxial layer in the epitaxial stack and an edge of the stop cap layer that is between 90° and 100°.

In some aspects, the techniques described herein relate to a fabrication method, wherein forming the sacrificial gate stack includes forming a corner residue deformity between a side of the epitaxial stack and a side of the sacrificial gate stack that has angle between a side of a second lowest sacrificial epitaxial layer in the epitaxial stack and an edge of the stop cap layer that is between 90° and 96°.

In some aspects, the techniques described herein relate to a fabrication method, wherein forming the sacrificial gate stack includes forming a corner residue deformity between a side of the epitaxial stack and a side of the sacrificial gate stack that has a curvature angle between a side of a third lowest sacrificial epitaxial layer in the epitaxial stack and an edge of the stop cap layer that is between 90° and 93°.

In some aspects, the techniques described herein relate to a fabrication method, wherein forming the sacrificial gate stack includes forming a corner residue deformity between a side of the epitaxial stack and a side of the sacrificial gate stack that has a dimension measured from the sacrificial gate stack to a sacrificial epitaxial layer in the sacrificial gate stack that is less than 2 nm.

In some aspects, the techniques described herein relate to a fabrication method, wherein the metal gate has a gap between the gate sidewall spacer and the inner spacer of less than 3 nm.

In some aspects, the techniques described herein relate to a fabrication method, wherein forming the metal gate includes forming the metal gate with a gap between the gate sidewall spacer and the inner spacer of less than 1 nm.

In some aspects, the techniques described herein relate to a fabrication method, wherein forming the metal gate includes forming the metal gate with a gap between the gate sidewall spacer and the inner spacer of 0.3 nm to 1 nm.

In some aspects, the techniques described herein relate to a fabrication method, wherein forming the metal gate includes forming the metal gate with a first critical dimension stop layer gap between a source/drain (S/D) region and an interfacial layer of the metal gate of greater than 3 nm.

In some aspects, the techniques described herein relate to a fabrication method, wherein forming the metal gate includes forming the metal gate with a first critical dimension stop layer gap between a source/drain (S/D) region and an interfacial layer of the metal gate of greater than 5 nm.

In some aspects, the techniques described herein relate to a fabrication method, wherein forming the metal gate includes forming the metal gate with a first critical dimension stop layer gap between a source/drain (S/D) region and an interfacial layer of the metal gate between 5 nm to 10 nm.

In some aspects, the techniques described herein relate to a fabrication method, wherein forming the metal gate includes forming a first inner spacer distance of between 0.3 nm to 1 nm that is defined between an end of an inner spacer to an end of a first spacer of the inner spacer, and a second inner spacer distance of between 5 nm to 8 nm that is defined between the end of the inner spacer to an end of a second spacer of the inner spacer.

In some aspects, the techniques described herein relate to a fabrication method, wherein forming the metal gate includes forming a first inner spacer distance less than 3 nm that is defined between an end of an inner spacer to an end of a first spacer of the inner spacer, and a second inner spacer distance less than 8 nm that is defined between the end of the inner spacer to an end of a second spacer of the inner spacer.

In some aspects, the techniques described herein relate to a fabrication method, wherein forming the metal gate includes forming a first inner spacer distance less than 1 nm that is defined between an end of an inner spacer to an end of a first spacer of the inner spacer, and a second inner spacer distance less than 8 nm that is defined between the end of the inner spacer to an end of a second spacer of the inner spacer.

In some aspects, the techniques described herein relate to a fabrication method, wherein forming the metal gate includes a first curvature angle of between 150° to 165° that is defined in an interfacial layer of the metal gate around a border between a gate sidewall spacer and an inner spacer for a lowest sacrificial epitaxial layer in the epitaxial stack.

In some aspects, the techniques described herein relate to a fabrication method, wherein forming the metal gate includes a first curvature angle of greater than 100° that is defined in an interfacial layer of the metal gate around a border between a gate sidewall spacer and an inner spacer for a lowest sacrificial epitaxial layer in the epitaxial stack.

In some aspects, the techniques described herein relate to a fabrication method, wherein forming the metal gate includes a second curvature angle of between 165° to 170° that is defined in an interfacial layer of the metal gate around a border between a gate sidewall spacer and an inner spacer for a second lowest sacrificial epitaxial layer in the epitaxial stack.

In some aspects, the techniques described herein relate to a fabrication method, wherein forming the metal gate includes a second curvature angle of greater than 130° that is defined in an interfacial layer of the metal gate around a border between a gate sidewall spacer and an inner spacer for a second lowest sacrificial epitaxial layer in the epitaxial stack.

In some aspects, the techniques described herein relate to a fabrication method, wherein forming the metal gate includes a third curvature angle of between 170° to 180° that is defined in an interfacial layer of the metal gate around a border between a gate sidewall spacer and an inner spacer for a third lowest sacrificial epitaxial layer in the epitaxial stack.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A fabrication method, comprising:
forming, on a substrate, an epitaxial stack comprising at least one sacrificial epitaxial layer and at least one channel epitaxial layer;
forming a plurality of fins in the epitaxial stack;
forming a stop cap layer over the plurality of fins and substrate, the stop cap layer having a substantial concentration of nitrogen (N);
forming a sacrificial gate stack on channel regions of the plurality of fins;
removing the sacrificial gate stack and sacrificial epitaxial layer; and
forming a metal gate, wherein the metal gate is shielded from source/drain features by a gate sidewall spacer, an inner spacer, and a first liner formed from the stop cap layer.

2. The fabrication method of claim 1, wherein the first liner has a concentration of N of between 2% and 10%.

3. The fabrication method of claim 1, wherein the first liner has a concentration of N of between 7% and 8%.

4. The fabrication method of claim 1, wherein forming the sacrificial gate stack comprises forming a corner residue deformity between a side of the epitaxial stack and a side of the sacrificial gate stack that has angle between a side of a lowest sacrificial epitaxial layer in the epitaxial stack and an edge of the stop cap layer that is between 90° and 100°.

5. The fabrication method of claim 1, wherein forming the sacrificial gate stack comprises forming a corner residue deformity between a side of the epitaxial stack and a side of the sacrificial gate stack that has angle between a side of a second lowest sacrificial epitaxial layer in the epitaxial stack and an edge of the stop cap layer that is between 90° and 96°.

6. The fabrication method of claim 1, wherein forming the sacrificial gate stack comprises forming a corner residue deformity between a side of the epitaxial stack and a side of the sacrificial gate stack that has a curvature angle between a side of a third lowest sacrificial epitaxial layer in the epitaxial stack and an edge of the stop cap layer that is between 90° and 93°.

7. The fabrication method of claim 1, wherein forming the sacrificial gate stack comprises forming a corner residue deformity between a side of the epitaxial stack and a side of the sacrificial gate stack that has a dimension measured from the sacrificial gate stack to a sacrificial epitaxial layer in the sacrificial gate stack that is less than 2 nm.

8. A semiconductor structure, comprising:
a fin comprising a plurality of nanosheets disposed over a substrate;
a gate structure disposed over a channel region of the plurality of nanosheets; and
a first liner formed in a gap between a gate sidewall spacer and an inner spacer, wherein the gate sidewall spacer, the inner spacer, and the first liner shield the gate structure from source/drain (S/D) features.

9. The semiconductor structure of claim 8, wherein the first liner has a concentration of N of between 2% and 10%.

10. The semiconductor structure of claim 8, wherein the gap between the gate sidewall spacer and the inner spacer is 0.3 nm to 1 nm.

11. The semiconductor structure of claim 8, wherein a first critical dimension stop layer gap between a source/drain (S/D) region and an interfacial layer of the gate structure is between 5 nm to 10 nm.

12. The semiconductor structure of claim 8, wherein a first inner spacer distance of between 0.3 nm to 1 nm is defined between an end of an inner spacer to an end of a first spacer of the inner spacer, and a second inner spacer distance of between 5 nm to 8 nm is defined between the end of the inner spacer to an end of a second spacer of the inner spacer.

13. The semiconductor structure of claim 8, wherein the fin comprises an epitaxial stack and a first curvature angle of between 150° to 165° is defined in an interfacial layer of the gate structure around a border between a gate sidewall spacer and an inner spacer for a lowest sacrificial epitaxial layer in the epitaxial stack.

14. The semiconductor structure of claim 8, wherein the fin comprises an epitaxial stack and a second curvature angle of between 165° to 170° is defined in an interfacial layer of the gate structure around a border between a gate sidewall spacer and an inner spacer for a second lowest sacrificial epitaxial layer in the epitaxial stack.

15. The semiconductor structure of claim 8, wherein the fin comprises an epitaxial stack and a third curvature angle of between 170° to 180° is defined in an interfacial layer of the gate structure around a border between a gate sidewall spacer and an inner spacer for a third lowest sacrificial epitaxial layer in the epitaxial stack.

16. A fabrication method, comprising:
depositing a stop cap layer over a fin having an epitaxial stack, the stop cap layer comprising with a concentration of at least 2% nitrogen (N);
forming a sacrificial gate stack on channel regions of the fin; and
replacing the sacrificial gate stack and a sacrificial epitaxial layer of the fin with a metal gate, wherein the metal gate is shielded from source/drain features by a gate sidewall spacer, an inner spacer, and a first liner formed from the stop cap layer.

17. The fabrication method of claim 16, wherein the first liner comprises SiCN, SiOCN, or SiON.

18. The fabrication method of claim 16, wherein the metal gate has a gap between the gate sidewall spacer and the inner spacer of less than 3 nm.

19. The fabrication method of claim 16, wherein forming the metal gate comprises forming the metal gate with a first critical dimension stop layer gap between a source/drain (S/D) region and an interfacial layer of the metal gate greater than 3 nm.

20. The fabrication method of claim 16, wherein forming the metal gate comprises forming a first inner spacer distance less than 3 nm that is defined between an end of an inner spacer to an end of a first spacer of the inner spacer, and a second inner spacer distance less than 8 nm that is defined between the end of the inner spacer to an end of a second spacer of the inner spacer.
